(19) United States
(12) Patent Application Publication
(10) Pub. No.: US 2010/0065845 A1
(43) Pub. Date: Mar. 18, 2010

(54) ORGANIC ELECTROLUMINESCENCE DISPLAY DEVICE

(76) Inventor: Masaya Nakayama, Kanagawa (JP)

Correspondence Address: BIRCH STEWART KOLASCH & BIRCH, PO BOX 747, FALLS CHURCH, VA, 22040-0747, US

(21) Appl. No.: 12/595,489

(22) PCT Filed: Apr. 3, 2008
(86) PCT No.: PCT/JP2008/057044

§ 371 Date: Oct. 9, 2009

(30) Foreign Application Priority Data
Apr. 10, 2007 (JP) 2007-103061
Jun. 28, 2007 (JP) 2007-170672

(51) Int. Cl. H01L 33/00; H01L 29/786

(52) U.S. Cl. 257/43; 257/59; 257/98; 257/40; 257/E29.296; 257/E33.004

(57) ABSTRACT

The invention provides an organic electroluminescent display device comprising: an organic electroluminescent element comprising an organic layer comprising a luminescent layer disposed between a pixel electrode and an upper electrode; and a drive TFT that supplies an electric current to the organic electroluminescent element, wherein: the drive TFT comprises a substrate, a gate electrode, a gate insulation film, an active layer, a source electrode and a drain electrode, and wherein: an resistive layer is provided between the active layer and at least one of the source electrode and the drain electrode.

### TECHNICAL FIELD

The present invention relates to an organic electroluminescence display device provided with an organic electroluminescence element and a TFT (a thin film transistor), more specifically, to an organic electroluminescence display device provided with a TFT using an improved amorphous oxide semiconductor. In the following, the TFT refers to an electric field effect type thin film transistor, unless otherwise specified.

### BACKGROUND ART

In recent years, with development of liquid crystals, electrolumimescence (EL) technologies and the like, flat panel display (FPD) devices have put into practical use. In particular, organic electrolumimescence elements (hereinafter, may be referred to as an organic EL element) using a thin film material that emits light when exited upon application of an electrical current, which can provide light emission of high luminance at low voltage, are expected to achieve reduction in thickness, weight, size, and power consumption of the devices in broad applications including cellular phone displays, personal digital assistants (PDA), computer displays, vehicle information displays, TV monitors, general illumination, and the like.

These FPDs are driven by a TFT active matrix circuit in which an amorphous silicon thin film or a polycrystalline silicon thin film provided on a glass substrate serves as an active layer.

Meanwhile, in pursuance of further improvements in thickness, weight and breakage resistance of the FPDs, it has been attempted to use a light weight and flexible resin substrate in place of a glass substrate.

However, since a production of a TFT employing the aforementioned silicon thin film requires a heating process at a relatively high temperature, it is difficult to form the film directly on a resin substrate whose heat resistance is generally low.

In view of the above, there have been active developments in TFTs in which an amorphous oxide such as In—Ga—Zn—O amorphous oxides that can form a layer at low temperature is employed for a semiconductor thin film (for example, see Japanese Patent Application Laid-Open (JP-A) No. 2006-165529 and IDW/AD'05 (Dec. 6, 2005), pp 845-846). Since TFTs employing an amorphous oxide semiconductor can be formed into a layer at room temperature, and therefore can be formed on a film, these have attracted attention recently as a material for an active layer. In particular, Hosono et. al, Tokyo Institute of Technology, has reported that the TFT employing an amorphous InGaXnO₄ (a-IGZO) has a field effect mobility of as high as about 10 cm²/Vs even on a PEN substrate, which is higher than that of an a-Si type TFT formed on a glass, and thus, the TFT has attracted attention particularly as a film TFT (for example, see Nature, Vol. 432 (Nov. 25, 2004), pp. 488-492).

However, when the TFT employing the a-IGZO is used, for example, for a drive circuit of a display device, the mobility of 1 cm²/Vs to 10 cm²/Vs is not a satisfiable characteristic, and also there are problems such as a high degree of off current and a low degree of on/off ratio. In particular, when the TFT is used for a drive TFT of an organic EL element in an organic EL display device, insufficient mobility and on/off ratio have made it difficult to obtain a high luminance organic EL display. Accordingly, further improvements in mobility and on/off ratio are required for the TFT in order to be used for driving an organic EL element.

Since the TFTs using an amorphous oxide semiconductor can be formed into a film at room temperature, and can be produced as a substrate of a flexible plastic film, these have attracted attention as a material for an active layer of a film (flexible) TFT. Specifically, as disclosed in JP-A No. 2006-165529, a TFT has been reported that is formed on a PET substrate and has performances of a field effect mobility of 10 cm²/Vs and on/off ratio of 10³ or more, by employing an In—Ga—Zn—O type oxide in a semiconductor layer (active layer). This amorphous oxide semiconductor TFT is, for example, suitable for use in a drive TFT or a switching TFT of a flexible organic EL display device employing a flexible plastic film as a substrate. However, in cases where the TFT is used as a drive TFT of an organic EL display device, sufficient properties of mobility and on/off ratio were not yet achieved and thus it was difficult to provide a high luminance organic EL display device. This was because, conventionally, when the concentration of electron carriers in an active layer is lowered in order to reduce the off current, the electron mobility was also reduced at the same time, thereby making it difficult to obtain a TFT having both of a favorable off property and a high mobility.

Further, there have been found problems that the organic EL display device having an organic EL element and a drive TFT that applies an electrical current to the organic EL element requires a high production cost due to multiple and complex production process thereof; tends to cause connection defects at connecting points of wiring lines; and tends to cause a short circuit electrically between a lower electrode and an upper electrode of the organic EL element.

In order to enhance luminance of an organic EL display device, the inventor has actively searched for means for enhancing the effect mobility and improving the on/off ratio of the TFT. As a result, it has been found as an effective means to design an organic EL display device to have a drive TFT including at least a substrate, a gate electrode, a gate insulation film, an active layer, a source electrode and a drain electrode, wherein the drive TFT further includes a resistive layer between the active layer and at least one of the source electrode and the drain electrode.

### DISCLOSURE OF INVENTION

An object of the present invention is to provide an organic EL display device with a high luminance, a high efficiency and a high reliability, and in particular, to provide an organic EL display device with a high luminance, a high efficiency and a high reliability that can be formed on a flexible resin substrate.

The above-described object will be carried out by the following means:

1. An organic electroluminescent display device comprising:

an organic electroluminescent element comprising an organic layer comprising a luminescent layer disposed between a pixel electrode and an upper electrode; and

a drive TFT that supplies an electric current to the organic electroluminescent element, wherein:

the drive TFT comprises a substrate, a gate electrode, a gate insulation film, an active layer, a source electrode and a drain electrode, and wherein:

a resistive layer is provided between the active layer and at least one of the source electrode and the drain electrode.

2. The organic electroluminescent display device according to 1, wherein the resistive layer has a smaller electroconductivity than that of the active layer.

3. The organic electroluminescent display device according to 1, wherein the active layer is in contact with the gate insulation film and the resistive layer is in contact with at least one of the source electrode and the drain electrode.

4. The organic electroluminescent display device according to 1, wherein the thickness of the resistive layer is greater than the thickness of the active layer.

5. The organic electroluminescent display device according to 1, wherein the electroconductivity between the resistive layer and the active layer changes continuously.

6. The organic electroluminescent display device according to 1, wherein the active layer and the resistive layer contain an oxide semiconductor.

7. The organic electroluminescent display device according to 6, wherein the oxide semiconductor is an amorphous oxide semiconductor.

8. The organic electroluminescent display device according to 6, wherein the oxygen concentration of the active layer is lower than the oxygen concentration of the resistive layer.

9. The organic electroluminescent display device according to 6, wherein the oxide semiconductor contains at least one selected from the group consisting of In, Ga and Zn, and a composite oxide thereof.

10. The organic electroluminescent display device according to 9, wherein the oxide semiconductor contains In and Zn, and wherein the composition ratio of Zn and In (expressed by Zn/In) of the resistive layer is higher than the composition ratio of Zn/In of the active layer.

11. The organic electroluminescent display device according to 1, wherein the electroconductivity of the active layer is 10⁻⁴ Scm⁻¹ or more and less than 10²Scm⁻¹.

12. The organic electroluminescent display device according to 1, wherein the ratio of the electroconductivity of the active layer to the electroconductivity of the resistive layer (electroconductivity of the active layer/electroconductivity of the resistive layer) is from 10² to 10⁸.

13. The organic electroluminescent display device according to 1, wherein the substrate is a flexible resin substrate.

14. The organic electroluminescent display device according to 1, wherein at least one of the source electrode and the drain electrode of the drive TFT, and the pixel electrode of the organic electroluminescent element, are made of the same material and are formed in the same process.

15. The organic electroluminescent display device according to 14, wherein the at least one of the source electrode and the drain electrode of the drive TFT is made of indium tin oxide or indium zinc oxide.

16. The organic electroluminescent display device according to 14, wherein an insulation film is formed on the periphery of the pixel electrode of the organic electroluminescent element.

According to the above configuration of the invention, a high luminance organic EL display device can be provided in which a drive TFT has a high carrier mobility and is capable of applying a high electrical current to an organic EL element. In particular, by producing a source electrode or a drain electrode of the TFT and a pixel electrode of the organic EL element from the same material in the same step, the production process can be simplified and the production cost can be reduced, and further the occurrence of defects can be suppressed by the reduced number of connecting portions between the wiring lines or the electrodes.

Additionally, by covering the periphery of the pixel electrode with an insulation layer, the short circuit between the electrodes (cathode and anode) can be prevented and a highly reliable display device can be provided.

Furthermore, by producing the source electrode or the drain electrode and the pixel electrode from the same material in the same process, or by producing an interlayer insulation film (a layer insulating the TFT from the pixel electrode) and an insulation film that prevents short circuit of the organic EL element from the same material in the same process, a highly reliable display device in which occurrence of defects such as short circuit is suppressed can be produced by the simplified production process at a reduced production cost.

### BRIEF DESCRIPTION OF DRAWINGS

Exemplary embodiments of the present invention will be described in detail based on the following figures, wherein:

FIGS. 1 to 4 are schematic views of the drive TFT and the organic EL element in the organic EL display device of the invention;

FIG. 5 is a schematic circuit diagram of the main part of the switching TFT, drive TFT and the organic EL element in the organic EL display device of the invention;

FIG. 6 is a schematic view showing of the insulation substrate in the production process of the organic EL display device of the invention;

FIGS. 7A to 7F are schematic views showing a formation process of the gate electrode and scanning wires in the production process of the organic EL display device of the invention;

FIG. 8 is a schematic view showing a formation process of the gate insulation film in the production process of the organic EL display device of the invention;

FIGS. 9A and 9B are schematic views showing a formation process of the active layer in the production process of the organic EL display device of the invention;

FIGS. 10A and 10B are schematic views showing a formation process of the source electrode, drain electrode and pixel electrode (anode) in the production process of the organic EL display device of the invention;

FIG. 11 is a schematic view showing a production process of the contact hole in the production process the organic EL display device of the invention;

FIGS. 12A and 12B are schematic views showing a production process of the connection electrode in the production process the organic EL display device of the invention;

FIG. 13 is a schematic view showing a formation process of the insulation film in the production process of the organic EL display device of the invention;

FIG. 14 is a schematic view showing a formation process of the organic EL element in the production process of the organic EL display device of the invention;

FIG. 15 is a schematic view showing a structure of the TFT in the organic EL display device according to the invention; and

FIG. 16 is a schematic view showing a structure of the top gate type TFT according to the organic EL display device of the invention.

### EFFECT OF THE INVENTION

According to the present invention, by employing a TFT including an amorphous oxide semiconductor that exhibits a high degree of field effect mobility and a high degree of on/off ratio as a drive TFT, an organic EL display device having a high luminance, high efficiency and high reliability can be provided. In particular, an organic EL display device having a high luminance, high efficiency and high reliability that can be formed on a flexible resin substrate can be provided.

### BEST MODE FOR CARRYING OUT THE INVENTION

### 1. TFT

The TFT of the present invention is an active element that includes at least a gate electrode, a gate insulation film, an active layer, a source electrode and a drain electrode in this order, and functions to control a current flowing into the active layer by applying a voltage to the gate electrode, and switch the current between the source electrode and the drain electrode. The structure of the TFT may be either a staggered structure or an inverted staggered structure.

In the present invention, a resistive layer is provided between the active layer and at least one of the source and drain electrodes, and is electrically connected to the active layer and the at least one of the source and drain electrodes. The electroconductivity of the resistive layer is preferably less than that of the active layer.

Preferably, at least the resistive layer and the active layer are formed on the substrate in the form of layers, wherein the active layer is in contact with the gate insulation film, and the resistive layer is in contact with at least one of the source electrode and the drain electrode.

The electroconductivity of the active layer is preferably 10⁻⁴ Scm⁻¹ or more and less than 10² Scm⁻¹, and is more preferably 10⁻¹ Scm⁻¹ or more and less than 10² Scm⁻¹. The electroconductivity of the resistive layer is preferably 10⁻² Scm⁻¹ or less, and is more preferably 10⁻⁹ Scm⁻¹ or more and less than 10⁻³ Scm⁻¹, which is less than the electroconductivity of the active layer. Moreover, the ratio of the electroconductivity of the active layer to the electroconductivity of the resistive layer (electroconductivity of the active layer/electroconductivity of the resistive layer) is preferably from 10² to 10⁸.

When the electroconductivity of the active layer is less than 10⁻⁴ Scm⁻¹, a sufficiently high level of electric field effect mobilitiy may not be obtained, and when it is 10² Scm⁻¹ or more, favorable on/off ratio may not be obtained.

In view of operation stability, the thickness of the resistive layer is preferably larger than the thickness of the active layer. More preferably, the ratio of the film thickness of the resistive layer to the film thickness of the active layer (film thickness of the resistive layer/film thickness of the active layer) is greater than 1 and no more than 100, and is further preferably greater than 1 and no more than 10.

In another embodiment, the electroconductivity between the resistive layer and the active layer preferably changes in a continuous manner.

In view of capability of layer formation at low temperature, the active layer and the resistive layer preferably contain an oxide semiconductor. In particular, the oxide semiconductor is preferably in an amorphous state.

The concentration of oxygen of the active layer is preferably lower than the concentration of oxygen of the resistive layer.

The oxide semiconductor preferably contains at least one selected from the group consisting of In, Ga and Zn, or a composite oxide thereof. More preferably, the oxide semiconductor contains In and Zn, where the composition ratio of Zn and In (the ratio of Zn to In expressed by Zn/In) in the resistive layer is greater than the composition ratio of Zn/In in the active layer. Moreover, the ratio of Zn/In of the resistive layer is preferably greater than the ratio of Zn/In of the active layer by an amount of 3% or more, and further preferably by an amount of 10% or more.

The substrate is preferably a flexible resin substrate.

1) Structure

Next, the configuration of the TFT used in the invention will be described.

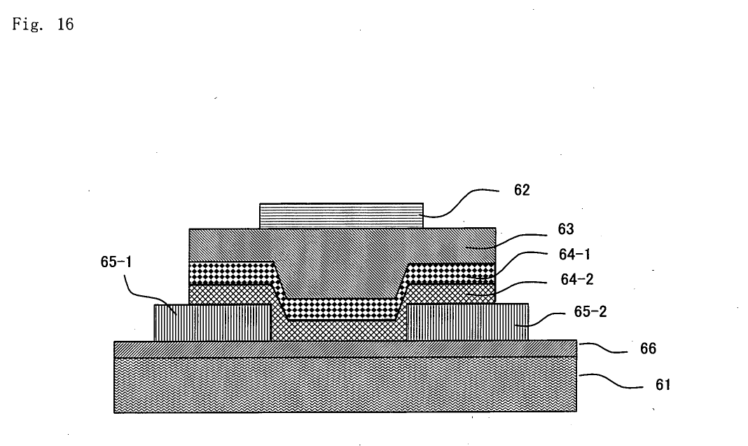

FIG. 15 is a schematic view of an example of the TFT of the invention having a reversed stagger structure. When a substrate 51 is a flexible substrate such as a plastic film, an insulation layer 56 is disposed on one surface of the substrate 51, and a gate electrode 52, a gate insulation layer 53, an active layer 54-1, and a resistive layer 54-2 are laminated thereon, and on the surface of which a source electrode 55-1 and a drain electrode 55-2 are provided. The active layer 54-1 is in contact with the gate insulation layer 53, and the resistive layer 54-2 is in contact with the source electrode 55-1 and the drain electrode 55-2. The compositions of the active layer and the resistive layer are determined so that the electroconductivity of the active layer when no voltage is applied to the gate electrode is higher than the electroconductivity of the resistive layer.

As regards the active layer and the resistive layer, oxide semiconductors disclosed in JP-A No. 2006-165529, e.g., In—Ga—Zn—O-based oxide semiconductors, may be used. It is known that in these oxide semiconductors, the higher the concentration of electron carriers is, the higher the electron mobility is. In other words, the higher the electroconductivity is, the higher the electron mobility is.

According to this structure of the invention, when the TFT is in an on-state when a voltage is applied to the gate electrode to form a channel, the active layer serving as a channel has high electroconductivity, and therefore the field effect mobility of the TFT is increased and a large on-current can be obtained. On the other hand, when the TFT is in an off-state, the off-current is kept low because the resistive layer having a high electric resistance lies between, and therefore the on-off ratio characteristic is remarkably improved.

The point of the structure of the TFT of the invention is to provide a semiconductor layer so that the electroconductivity of the semiconductor layer in the vicinity of the gate insulation film is higher than the electroconductivity of the semiconductor layer in the vicinity of source and drain electrodes (here, the “semiconductor layer” refers to a layer including an active layer and a resistive layer). As long as this condition is achieved, the means for achieving this is not only limited to an embodiment shown in FIG. 15 in which the conductive layer has a two-layer structure. The semiconductor layer may have a multilayer structure of three or more, or alternatively, the electroconductivity of the semiconductor layer may be changed in a continuous manner.

FIG. 16 is a schematic diagram showing another exemplary embodiment of the TFT of the invention having a top gate structure. When a substrate 61 is a flexible substrate such as a plastic film, an insulation layer 66 is disposed on one surface of the substrate 61, a source electrode 65-1 and a drain electrode 65-2 are provided on the insulation layer, and active layer 64-2 and a resistive layer 64-1 are laminated thereon, and thereafter a gate insulation film 63 and a gate electrode 62 are provided. In a similar manner to the case of the reversed stagger structure, the active layer (high-electroconductivity layer) is in contact with the gate insulation film 63 and the resistive layer (low-electroconductivity layer) is in contact with the source electrode 65-1 and the drain electrode 65-2. The compositions of the active layer 64-1 and the resistive layer 64-2 are determined so that the electroconductivity of the active layer 64-1 when no voltage is applied to the gate electrode 62 is higher than the electroconductivity of the resistive layer 64-2.

2) Electroconductivity

Now, the electroconductivity of the active layer and the resistive layer in the invention will be explained.

The electroconductivity is a value of a physical property which indicates a degree of electric conduction that a substance can perform. The electroconductivity σ of a substance can be expressed by the following formula, where the carrier concentration of the substance is denoted by n, the carrier mobility is denoted by μ, and e is the elementary charge.

σ=neμ

When the active layer or the resistive layer is composed of an n-type semiconductor, electrons serve as the carrier. In this case, the carrier concentration refers to the concentration of electron carriers, and the carrier mobility refers to the electron mobility. Conversely, when the active layer or the resistive layer is composed of a p-type semiconductor, electron holes serve as the carrier. In this case, the carrier concentration refers to the concentration of hole carriers, and the carrier mobility refers to the hole mobility. Further, the carrier concentration and carrier mobility of a substance can be determined by Hall measurements.

<Method of Determining Electroconductivity>

The electroconductivity of a film can be determined by measuring the sheet resistance of the film having a known thickness. The electroconductivity of a semiconductor changes depending on the temperature, and the electroconductivity cited herein refers to the electroconductivity at room temperature (20° C.).

3) Gate Insulation Film

An insulator such as SiO₂, SiNₓ, SiON, Al₂O₃, Y₂O₃, Ta₂O₅, HfO₂ and the like, or mixed crystal compounds containing two or more of these may be used for the gate insulation film. Also, a polymeric insulator such as polyimide may be used for the gate insulation film.

It is preferable that the gate insulation film has a thickness of from 10 nm to 10 μm. The gate insulation film needs to have a certain degree of the thickness in order to reduce the amount of a leak current and enhance the voltage resistance. However, when the thickness of the gate insulation film is increased, the voltage for driving the TFT may be increased. Therefore, the thickness of the gate insulation film is preferably from 50 nm to 1000 nm for an inorganic insulator, and from 0.5 μm to 5 μm for a polymeric insulator. It is particularly preferable to use an insulator with a high dielectric constant, such as HfO₂, for the gate insulation film, because the TFT can be driven with a low voltage even with an increased thickness.

4) Active Layer and Resistive Layer

For the active layer and the resistive layer of the present invention, an oxide semiconductor is preferably used. Among these, an amorphous oxide semiconductor is particularly preferable, since it can be formed into a film at low temperature and can be provided on a flexible resin substrate such as a plastic sheet. Examples of the preferable amorphous oxide semiconductors that can be processed at low temperature include those disclosed in JP-A No. 2006-165529 such as an oxide containing In, an oxide containing In and Zn, and an oxide containing In, Ga and Zn. As regards their compositional structures, it is known that amorphous oxide semiconductors of InGaO₃(ZnO)ₘ (m is a natural number less than 6) are preferable. These oxide semiconductors are n-type semiconductors in which electrons serve as carriers. Of course, p-type oxide semiconductors such as ZnO/Rh₂O₃, CuGaO₂, and SrCu₂O₂ may be used for the active layer and the resistive layer.

Specifically, an amorphous oxide semiconductor according to the invention is preferably composed including In—Ga—Zn—O. The amorphous oxide semiconductor is more preferably an amorphous oxide semiconductor with a composition of InGaO₃(ZnO)ₘ (m is a natural number less than 6) in a crystalline state, and in InGaZnO₄ is particularly preferable. An amorphous oxide semiconductor of the above composition has such a feature that the electron mobility tends to increase as the electroconductivity increases. In addition, it is disclosed in JP-A No. 2006-165529 that the electroconductivity can be controlled by regulating the partial pressure of oxygen during film formation.

Inorganic semiconductors such as Si and Ge, compound semiconductors such as GaAs, and organic semiconductor materials such as pentacene and polythiophene, carbon nanotubes and the like may also be used for the active layer and the resistive layer, other than oxide semiconductors.

<Electroconductivity of Active Layer and Resistive Layer>

In the present invention, the electroconductivity of the active layer in the vicinity of the gate insulation film is higher than the electroconductivity of the resistive layer.

The ratio of the electroconductivity of the active layer to the electroconductivity of the resistive layer (the electroconductivity of the active layer/the electroconductivity of the resistive layer) is preferably from 10¹ to 10¹⁰, and is more preferably from 10² to 10⁸. The electroconductivity of the active layer is preferably 10⁻⁴ Scm⁻¹ or more and less than 10² Scm⁻¹, and is more preferably 10⁻¹ Scm⁻¹ or more and less than 10² Scm⁻¹.

The electroconductivity of the resistive layer is preferably 10⁻² Scm⁻¹ or less, and is more preferably 10⁻⁹ Scm⁻¹ or more and less than 10⁻³ Scm⁻¹.

<Film Thicknesses of Active Layer and Resistive Layer>

The film thickness of the resistive layer is preferably larger than that of the active layer. More preferably, the ratio represented by the film thickness of the resistive layer/the film thickness of the active layer is preferably greater than 1 and no more than 100, and is more preferably greater than 1 and no more than 10.

The film thickness of the active layer is preferably 1 nm or more and no more than 100 nm, and is more preferably 2.5 nm or more and no more than 30 nm. The film thickness of the resistive layer is preferably 5 nm or more and no more than 500, and is more preferably 10 nm or more and no more than 100 nm.

By employing the active layer and the resistive layer having the above structure, a TFT characteristic such as an on-off ratio of as high as 10⁶ or more can be achieved in a TFT having a mobility of as high as 10 cm²/V·sec or more.

<Means for Adjusting Electroconductivity>

When the active layer and the resistive layer are composed of an oxide semiconductor, the following can be mentioned as the means for adjusting the electroconductivity of the active layer and the resistive layer.

(1) Adjustment by Oxygen Defects

It is known that when oxygen defects are created in an oxide semiconductor, carrier electrons are generated and therefore the electroconductivity is increased. Hence, the electroconductivity of an oxide semiconductor can be controlled by adjusting the quantity of oxygen defects. Specifically, means for controlling the quantity of oxygen defects include regulating the partial pressure of oxygen during film formation, regulating the oxygen concentration and the treatment time of the post-treatment after the film formation. Specifically, examples of the post-treatments include those employing a heating temperature of 100° C. or higher, oxygen plasma, or UV ozone. Among these, the method of controlling the partial pressure of oxygen during film formation is preferable in view of productivity. It has been disclosed in JP-A No. 2006-165529 that the electroconductivity of an oxide semiconductor can be controlled by adjusting the partial pressure of oxygen during film formation, which can be applied in the present invention.

(2) Adjustment by Composition Ratio

It is known that the electroconductivity can be changed by changing the composition ratio of metals in an oxide semiconductor. For instance, it has been disclosed in JP-A No. 2006-165529 that in InGaZn₁₋ₓMgₓO₄, the electroconductivity is decreased as the concentration of Mg is increased. In addition, it has been reported that the electroconductivity of oxides of (In₂O₃)₁₋ₓ(ZnO)ₓ is decreased as the concentration of Zn is increased, when the Zn/In ratio is 10% or higher (“TOMEI DOUDENMAKU NO SINTENKAI II (Developments of Transparent Conductive Films II)”, pages 34-35, CMC Publishing CO., LTD.). As a specific means for changing the composition ratio, for example, when film formation is performed by sputtering, a method can be mentioned in which targets having different composition ratios are used. Alternatively, the composition ratio of the layer may be changed by performing co-sputtering using multiple targets and regulating the sputtering ratios of the targets individually.

(3) Adjustment by Impurities

It is disclosed in JP-A No. 2006-165529 that by adding elements such as Li, Na, Mn, Ni, Pd, Cu, Cd, C, N, and P to an oxide semiconductor as an impurity, the concentration of electron carriers can be reduced, and therefore the electroconductivity can be decreased. The addition of an impurity can be performed by performing co-vapor deposition of the oxide semiconductor and the impurity, performing ion-doping with ions of the impurity element to an oxide semiconductor film which has already been formed.

(4) Adjustment by Oxide Semiconductor Material

In the above items (1) to (3) are mentioned the methods of adjusting the electroconductivity within the same oxide semiconductor system. However, the electroconductivity can also be changed by changing the type of oxide semiconductor material. It is known that SnO₂-based oxide semiconductors have lower electroconductivity than that of In₂O₃-based oxide semiconductors. In particular, oxide insulator materials such as Al₂O₃, Ga₂O₃, ZrO₂, Y₂O₃, Ta₂O₃, MgO, and HrO₃ are known as oxide materials having lower electroconductivity.

As the means for adjusting the electroconductivity, the means stated in the above (1) to (4) may be employed independently or in combination.

<Method of Forming Active Layer and Resistive Layer>

As the means for forming the active layer and the resistive layer, a vapor-phase film forming method using, as a target, a polycrystalline sintered compact of an oxide semiconductor can be suitably employed. Among the vapor-phase film forming methods, a sputtering method and a pulsed laser deposition method (PLD method) are preferable, and sputtering method is more preferable for mass production.

For instance, the active layer can be formed by an RF magnetron sputtering deposition method while controlling the vacuum level and flow rate of oxygen. The electroconductivity can be reduced by increasing the flow rate of oxygen.

Whether the obtained film is amorphous or not can be determined by known X-ray diffraction methods.

The thickness of the film can be determined by contact stylus-type surface profile measurement. The composition ratio can be determined by RBS analysis (Rutherford Backscattering Spectrometry).

5) Gate Electrode

In the invention, the following can be mentioned as the preferable materials for the gate electrode: metals such as Al, Mo, Cr, Ta, Ti, Au or Ag, alloys such as Al—Nd and APC; conductive films of metal oxides such as tin oxide, zinc oxide, indium oxide, indium-tin oxide (ITO), or indium-zinc oxide (IZO); organic conductive compounds such as polyaniline, polythiophene, or polypyrrole; and combinations thereof. The thickness of the gate electrode is preferably from 10 nm to 1000 nm.

The method of forming the electrode is not particularly limited, and the electrode can be formed on the substrate according to a method that is appropriately selected in view of the characteristics of the material or the like, from the methods such as: wet methods such as a printing method and a coating method, physical methods such as a vacuum deposition method, a sputtering method and an ion plating method, chemical methods such as a CVD method and a plasma CVD method, and the like. For example, when ITO is selected as the material for the electrode, the electrode can be formed according to a DC or RF sputtering method, a vacuum deposition method, an ion plating method or the like. Further, when an organic conductive compound is selected as the material for the electrode, the electrode can be formed according to a wet film-forming method or the like.

6) Source Electrode and Drain Electrode

In the invention, the following can be mentioned as the suitable materials for the source electrode and the drain electrode: metals such as Al, Mo, Cr, Ta, Ti, Au and Ag; alloys such as Al—Nd and APC; conductive films of metal oxides such as tin oxide, zinc oxide, indium oxide, indium-tin oxide (ITO) and indium-zinc oxide (IZO); and organic conductive compounds such as polyaniline, polythiophene and polypyrrole, and combinations thereof. The thicknesses of the source electrode and the drain electrode are preferably from 10 nm to 1000 nm.

The method of forming the electrodes is not particularly limited, and the electrodes can be formed on the substrate according to a method that is appropriately selected in view of the characteristics of the material or the like, from the methods such as: wet methods such as a printing method and a coating method, physical methods such as a vacuum deposition method, a sputtering method and an ion plating method, chemical methods such as a CVD method and a plasma CVD method, and the like. For example, when ITO is selected as the material for the electrodes, the electrodes can be formed according to a DC or RF sputtering method, a vacuum deposition method, an ion plating method or the like. Further, when an organic conductive compound is selected as the material for the electrodes, the electrodes can be formed according to a wet film-forming method or the like.

7) Substrate

The substrate used in the invention is not particularly limited, and the following can be mentioned as the suitable materials for the substrate: inorganic materials such as YSZ (yttria-stabilized zirconia) and glass; and organic materials such as synthetic resins including polyesters such as polyethylene terephthalate, polybutylene terephthalate and polyethylene naphthalate, polystyrene, polycarbonate, polyether sulfone, polyarylate, allyl diglycol carbonate, polyimide, polycycloolefin, norbornene resins, and polychlorotrifluoroethylene. The aforementioned organic materials are preferably superior in heat resistance, stability of dimension, resistance to solvents, electric insulation property, processability, low gas permeability, low hygroscopicity, and the like.

In the present invention, a flexible substrate is particularly preferably used. As the material for the flexible substrate, an organic plastic film which has high transmittance is preferable, and the following can be mentioned as the suitable materials: polyesters such as polyethylene terephthalate, polybutylene phthalate and polyethylene naphthalate, polystyrene, polycarbonate, polyether sulfone, polyarylate, polyimide, polycycloolefin, norbornene resins, polychlorotrifluoroethylene, and the like. It is also preferable to provide the film-shaped plastic substrate with an insulation layer if the insulation property of the substrate insufficient, a gas-barrier layer for preventing moisture and oxygen from penetrating through the substrate, an undercoat layer for improving the planarity and the adhesion with the electrode or active layer of the substrate, or the like.

The thickness of the flexible substrate is preferably from 50 nm to 500 μm. When the thickness of the flexible substrate is less than 50 μm, it may be difficult to maintain sufficient planarity of the substrate, and when thickness of the flexible substrate is more than 500 μm, it may be difficult to bend the substrate itself freely, i.e., the flexibility of the substrate may be insufficient.

8) Protective Insulation Film

As necessary, a protective insulation film may be provided on the TFT. The protective insulation film serves to protect the semiconductor layer of the active layer or the resistive layer from degradation due to air, or to insulate an electronic device formed on the TFT from the TFT.

Specific examples of the material for the protective insulation film include metal oxides such as MgO, SiO, SiO₂, Al₂O₃, GeO, NiO, CaO, BaO, Fe₂O₃, Y₂O₃ and TiO₂, metal nitrides such as SiNₓ and SiNₓO_{y}, metal fluorides such as MgF₂, LiF, AlF₃ and CaF₂, polyethylene, polypropylene, polymethyl methacrylate, polyimide, polyurea, polytetrafluoroethylene, polychlorotrifluoroethylene, polydichlorodifluoroethylene, a copolymer of chlorotrifluorodethylene and dichlorodifluoroethylene, a copolymer obtained by copolymerizing a monomer mixture containing tetrafluoroethylene and at least one co-monomer, a fluorine-containing copolymer having a cyclic structure in a copolymerization main chain, a water-absorbing material having a water absorption of 1% or more, and a moisture-poof material having a water absorption of no more than 0.1%.

The method for forming the protective insulation layer is not particularly limited and may be selected from, for example, a vacuum deposition method, a sputtering method, a reactive sputtering method, an MBE (molecular beam epitaxy) method, a cluster ion beam method, an ion plating method, a plasma polymerization method (high-frequency excitation ion plating method), a plasma CVD method, a laser CVD method, a thermal CVD method, a gas source CVD method, a coating method, a printing method, and a transfer method.

9) Post Treatment

As necessary, a thermal treatment may be conducted as a post treatment for the TFT. The thermal treatment is conducted at 100° C. or more in atmospheric air or nitrogen atmosphere. The thermal treatment may be conducted either after the formation of the semiconductor layer or after the production of the TFT. By performing the thermal treatment, effects such as suppressed in-plane irregularity of the TFT characteristics or improved driving stability can be obtained.

### 2. Organic EL Element

The organic EL element according to the present invention has, on a substrate, a pixel electrode and an upper electrode, and in between these electrodes an organic compound layer including an organic luminescent layer (hereinafter, referred simply to as a “luminescent layer” in some cases). In view of the nature of the EL element, it is preferred that at least one of the pixel electrode and the upper electrode is transparent. Either the pixel electrode or the upper electrode serves as an anode and, the other serves as a cathode. Typically, the pixel electrode serves as the anode and the upper electrode serves as the cathode.

The organic compound layer in the invention preferably has a structure in which a hole transport layer, a luminescent layer, and an electron transport layer are laminated in this order from the anode side. Further, a hole injection layer may be provided between the hole transport layer and the anode, and/or an electron injection intermediate layer may be provided between the cathode and the electron transport layer. Each layer thereof may be constructed by plural secondary layers. Moreover, a hole transport intermediate layer may be provided between the luminescent layer and the hole transport layer, and an electron injection layer may be provided between the cathode and the electron transport layer. Each layer may include one or more secondary layers.

Each layer that constitutes the organic compound layer can be formed by any appropriate method including dry film formation methods such as vapor deposition method and sputtering method, transfer method, printing method, application method, ink jet method, spray method and the like.

In the following, the organic electroluminescent element of the present invention will be described in detail.

(Substrate)

In the present invention, the substrate is preferably one that does not scatter or attenuate the light emitted from the organic compound layer. Specific examples of materials for the substrate include inorganic materials such as yttria-stabilized zirconia (YSZ) and glass, and organic materials including polyesters such as polyethylene terephthalate, polybutylene phthalate and polyethylene naphthalate, polystyrene, polycarbonate, polyether sulfone, polyarylate, polyimide, polycycloolefin, norbornene resins, poly(chlorotrifluoroethylene), and the like.

For instance, when glass is used for the substrate, non-alkali glass is preferably used in view of reducing the amount of ions eluted from the glass. In the case of employing a soda-lime glass substrate, it is preferred to provide a barrier coat of silica and the like onto the glass. In the case of employing an organic material, the material are preferably superior in heat resistance, dimension stability, solvent resistance, electrical insulation, processability and the like.

The shape, structure, size or the like of the substrate may be suitably selected without particularly limited according to application, purposes and the like of the luminescent element. In general, the shape of the substrate is preferably plate-like. The structure of the substrate may be a monolayer structure or a laminated structure. Furthermore, the substrate may be composed of a single member or two or more members.

Although the substrate may be transparent and colorless, or transparent and colored, it is preferred that the substrate is transparent and colorless from the viewpoint that the substrate does not scatter or attenuate the light emitted from the organic luminescent layer.

A moisture permeation preventive layer (gas barrier layer) may be provided on the front surface or the back surface of the substrate.

As the material for the moisture permeation preventive layer (gas barrier layer), inorganic substances such as silicon nitride and silicon oxide may be preferably employed. The moisture permeation preventive layer (gas barrier layer) may be formed by, for example, a high-frequency sputtering method or the like.

In the case where a thermoplastic substrate is used, a hardcoat layer, an undercoat layer and the like may be further provided as needed.

(Anode)

The anode may generally be selected from any known electrode materials according to the application and purpose of the luminescent device, as long as it functions as an electrode that supplies electron holes to the organic compound layer, and there is no particular limitation as to the shape, the structure, the size or the like. As mentioned above, the anode is usually provided as a transparent anode.

As the materials for the anode, for example, metals, alloys, metal oxides, electroconductive compounds, and mixtures thereof can be preferably mentioned. Specific examples of the anode materials include electroconductive metal oxides such as tin oxide doped with antimony (ATO), doped with fluorine (FTO) or the like, tin oxide, zinc oxide, indium oxide, indium tin oxide (ITO), and indium zinc oxide (IZO); metals such as gold, silver, chromium, and nickel; mixtures or laminates of these metals and the electroconductive metal oxides; inorganic electroconductive materials such as copper iodide and copper sulfide; organic electroconductive materials such as polyaniline, polythiophene, and polypyrrole; and laminates of these materials and ITO. Among these, the electroconductive metal oxides are preferred, and ITO is particularly preferable in view of productivity, high electroconductivity, transparency and the like.

The anode may be formed on the substrate in accordance with a method that may be appropriately selected from wet methods such as printing methods, a coating method and the like, physical methods such as a vacuum deposition method, a sputtering method, and ion plating methods and the like; and chemical methods such as a CVD method, a plasma CVD method and the like, in consideration of the compatibility with the material for the anode. For instance, when ITO is selected as the material, the anode may be formed in accordance with a DC or high-frequency sputtering method, a vacuum deposition method, an ion plating method or the like.

In the organic EL element of the present invention, the position at which the anode is formed is not particularly limited, and may be appropriately selected according to the application and purpose of the luminescent device. However, the anode may be formed on the substrate. In this case, the anode may be formed on a part of the surface of the substrate, or may be formed on the entire surface of the substrate.

The patterning process for forming the anode may be performed by chemical etching such as photolithography, physical etching such as etching with a laser, vacuum deposition or sputtering by superposing a mask, a lift-off method, a printing method, or the like.

The thickness of the anode may be suitably selected according to the material that constitutes the anode, and is not categorically determined. However, the thickness is usually from around 10 nm to 50 μm, and is preferably from 50 nm to 20 μm.

The value of resistance of the anode is preferably 10³Ω/square or less, and is more preferably 10²Ω/square or less. In the case where the anode is transparent, it may have a color or not. In order to take out the light emitted from the transparent anode side, it is preferred that a light transmittance of the anode is 60% or higher, and is more preferably 70% or higher.

Concerning transparent anodes, there is a detailed description in “TOUMEI DENNKYOKU-MAKU NO SHINTENKAI (Novel Developments in Transparent Electrode Films)” edited by Yutaka Sawada, published by C.M.C. in 1999, the contents of which are incorporated by reference herein. In the case where a plastic substrate having a low heat resistance is used, the anode is preferably a transparent anode formed using ITO or IZO at a film formation temperature of as low as 150° C. or less.

(Cathode)

The cathode may be appropriately selected from known electrode materials according to the application and purpose of the luminescent device, and may generally be any material as long as it functions as an electrode to inject electrons to the organic compound layer, without particularly limited according to the shape, structure, size or the like thereof.

The materials for the cathode may include, for example, metals, alloys, metal oxides, electroconductive compounds, and combinations thereof. Specific examples thereof include alkali metals (e.g., Li, Na, K, Cs), alkaline earth metals (e.g., Mg, Ca), gold, silver, lead, aluminum, sodium-potassium alloys, lithium-aluminum alloys, magnesium-silver alloys, rare earth metals such as indium, and ytterbium, and the like. These may be used alone, but are preferably used in combination of two or more from the viewpoint of satisfying both stability and electron injectability.

Among these, as the materials for constituting the cathode, alkaline metals or alkaline earth metals are preferred in view of electron injectability, and materials containing aluminum as a major component are preferred in view of excellent preservation stability.

The “material containing aluminum as a major component” refers to aluminum itself, alloys of aluminum and 0.01% by weight to 10% by weight of an alkaline metal or an alkaline earth metal, or mixtures thereof (e.g., lithium-aluminum alloys, magnesium-aluminum alloys and the like).

Regarding materials for the cathode, detailed description thereof can be found in detail in JP-A Nos. 2-15595 and 5-121172, the disclosure of which are incorporated by reference herein. The materials described here may be applied in the present invention.

A method for forming the cathode is not particularly limited, and any known method may be applied.

For instance, the cathode may be formed in accordance with a method appropriately selected in consideration of the compatibility with the material for the cathode, and the method may be wet methods such as a printing method, a coating method and the like; physical methods such as a vacuum deposition method, a sputtering method, an ion plating method and the like; and chemical methods such as a CVD method and a plasma CVD methods and the like. For example, when a metal (or metals) is (are) selected as the material (or materials) for the cathode, one or more of these may be applied at the same time, or in a sequential manner, in accordance with a sputtering method or the like.

The patterning for formation of the cathode may be performed by a method selected from chemical etching such as photolithography, physical etching such as etching with a laser, vacuum deposition or sputtering by superposing a mask, a lift-off method, a printing method, and the like.

In the present invention, the position at which the cathode is formed is not particularly limited, and it may be formed on a part of the surface of the organic compound layer or on the entire surface of the organic compound layer.

Furthermore, a dielectric material layer made of a fluoride, oxide or the like of an alkaline metal or an alkaline earth metal may be interposed in between the cathode and the organic compound layer at a thickness of from 0.1 nm to 5 nm. The dielectric layer may be assumed as a kind of electron injection layer. The dielectric material layer may be formed in accordance with, for example, a vacuum deposition method, a sputtering method, an ion-plating method or the like.

The thickness of the cathode may be appropriately selected according to the material for the cathode, and is therefore not categorically determined. However, the thickness is usually in the range of around 10 nm to 5 μm, and is preferably 50 nm to 1 μm.

Moreover, the cathode may be transparent or opaque. The transparent cathode can be formed by applying a material for the cathode at a thickness of 1 nm to 10 nm, and then laminating a transparent electroconductive material such as ITO or IZO thereon.

(Organic Compound Layer)

The organic EL element of the present invention has at least one organic compound layer including a luminescent layer. Examples of the organic compound layer other than the luminescent layer include a hole transport layer, an electron transport layer, a hole blocking layer, an electron blocking layer, a hole injection layer, an electron injection layer, and the like.

The respective layers that constitute the organic compound layer in the present invention can be preferably formed by any method selected from dry film formation methods such as a vapor deposition method and a sputtering method, a wet coating method, a transferring method, a printing method, an ink jet method, and the like.

(Luminescent Layer)

The luminescent layer is a layer having a function of, upon application of an electric field, receiving electron holes from the anode, electron hole injection layer, or electron hole transport layer, and receiving electrons from the cathode, electron injection layer, or electron transport layer, thereby providing a field for recombination of the electron holes and the electrons to emit light.

The luminescent layer in the present invention may be composed of a luminescent material alone, or a mixture of a host material and a luminescent dopant. The luminescent dopant may be a fluorescent material or a phosphorescent material, and two or more of these may be used in combination. The host material is preferably an electron transport material. The host material may be used alone or two or more, and a combination of an electron transporting host material and a hole transporting host material can be mentioned. Further, a material that does not have an electron transport property or luminescent property may be contained in the luminescent layer.

The luminescent layer may be composed of a single layer or two or more layers, and each layer may emit light of different color from others.

In the present invention, either a phosphorescent material or a fluorescent materials may be used as the luminescent dopant.

The luminescent layer of the present invention may include two or more of luminescent dopants for the purpose of improving color purity and widening the luminescent wavelength area. The luminescent dopant in the present invention preferably satisfies at least one of the relationships of 1.2 eV>ΔIp>0.2 eV and 1.2 eV>ΔEa>0.2 eV, with respect to the host material, in view of driving durability.

<Phosphorescent Dopant>

Examples of the above-described phosphorescent dopant generally include a complex containing a transition metal atom or a lantanoid atom.

For instance, although the transition metal atoms are not limited, they are preferably ruthenium, rhodium, palladium, tungsten, rhenium, osmium, iridium, or platinum; more preferably rhenium, iridium, and platinum; and still more preferably iridium or platinum.

Examples of the lantanoid atoms include lanthanum, cerium, praseodymium, neodymium, samarium, europium, gadolinium, terbium, dysprosium, holmium, erbium, thulium, ytterbium, and lutetium, and among these lantanoid atoms, neodymium, europium, and gadolinium are preferred.

Examples of the ligands in the complex include the ligands described, for example, in “Comprehensive Coordination Chemistry” authored by G. Wilkinson et al., published by Pergamon Press Company in 1987; “Photochemistry and Photophysics of Coordination compounds” authored by H. Yersin, published by Springer-Verlag Company in 1987; and “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982.

Specific examples of the ligands include, preferably, halogen ligands (preferably chlorine ligands), aromatic carbocyclic ligands (e.g., those having carbon atoms of preferably 5 to 30, more preferably 6 to 30, still more preferably 6 to 20 and particularly preferably 6 to 12, such as cyclopentadienyl anions, benzene anions, naphthyl anions), nitrogen-containing heterocyclic ligands (e.g., those having carbon atoms of preferably 5 to 30, more preferably 6 to 30, still more preferably 6 to 20 and particularly preferably 6 to 12 such as phenylpyridine, benzoquinoline, quinolinol, bipyridyl, and phenanthroline), diketone ligands (e.g., acetylacetone and the like), carboxylic acid ligands (e.g., those having carbon atoms of preferably 2 to 30, more preferably 2 to 20, and still more preferably 2 to 16, such as acetic acid ligands), alcoholate ligands (e.g., those having carbon atoms of preferably 1 to 30, more preferably 1 to 20, and still more preferably 6 to 20, such as phenolate ligands), silyloxy ligands (e.g., those having carbon atoms of preferably 3 to 40, more preferably 3 to 30, still more preferably 3 to 20, and particularly preferably 6 to 20, such as trimethylsilyloxy ligands, dimethyl-tert-butylsilyloxy ligands, and triphenylsilylocy ligands), carbon monoxide ligands, isonitryl ligands, cyano ligands and phosphorous ligands (those having carbon atoms of preferably 3 to 40, more preferably 3 to 30, still more preferably 3 to 20, and particularly preferably 6 to 20, such as triphenyl phosphine ligands), thiolato ligands (those having carbon atoms of preferably 1 to 30, more preferably 1 to 20, still more preferably 6 to 20, such as phenylthiolato ligands), and phosphine oxide ligands (those having carbon atoms of 3 to 30, more preferably 8 to 30, and still more preferably 18 to 30, such as triphenylphosphine oxide ligands). Among these, nitrogen-containing heterocyclic ligands are most preferable.

The above-described complexes may a complex containing a single transition metal atom, or a so-called polynuclear complex containing two or more transition metal atoms that may be the same or different from each other.

Among these, specific examples of the luminescent dopants include phosphorescent compounds described in patent documents such as U.S. Pat. No. 6,303,238B1, U.S. Pat. No. 6,097,147, WO00/57676, WO00/70655, WO01/08230, WO01/39234A2, WO01/41512A1, WO02/02714A2, WO02/15645A1, WO02/44189A1, WO05/19373A2, JP-A No. 2001-247859, JP-A No. 2002-302671, JP-A No. 2002-117978, JP-A No. 2003-133074, JP-A No. 2002-235076, JP-A No. 2003-123982, JP-A No. 2002-170684, EP1211257, JP-A No. 2002-226495, JP-A No. 2002-234894, JP-A No. 2001-247859, JP-A No. 2001-298470, JP-A No. 2002-173674, JP-A No. 2002-203678, JP-A No. 2002-203679, JP-A No. 2004-357791, JP-A No. 2006-256999, JP-A No. 2007-19462, JP-A No. 2007-84635, and JP-A No. 2007-96259. Among these, more preferred are the luminescent dopants include Ir complexes, Pt complexes, Cu complexes, Re complexes, W complexes, Rh complexes, Ru complexes, Pd complexes, Os complexes, Eu complexes, Tb complexes, Gd complexes, Dy complexes, and Ce complexes; still more preferred are Ir complexes, Pt complexes, and Re complexes; and particularly preferred are the Ir complexes, Pt complexes and Re complexes containing at least one coordination form of metal-carbon bonds, metal-nitrogen bonds, metal-oxygen bonds, and metal-sulfur bonds. Among these, the Ir complexes, Pt complexes and Re complexes containing a multidentate ligand having three or more bonding sites are most preferable from the viewpoints of luminescence efficiency, driving durability, chromaticity and the like.

<Fluorescenct Dopant>

Examples of the above-described fluorescenct dopants generally include benzoxazole, benzoimidazole, benzothiazole, styrylbenzene, polyphenyl, diphenylbutadiene, tetraphenylbutadiene, naphthalimide, coumarin, pyran, perinone, oxadiazole, aldazine, pyralidine, cyclopentadiene, bis-styrylanthracene, quinacridone, pyrrolopyridine, thiadiazolopyridine, cyclopentadiene, styrylamine, aromatic dimethylidene compounds, condensed polyaromatic compounds (anthracene, phenanthroline, pyrene, perylene, rubrene, pentacene and the like), metal complexes represented by metal complexes of 8-quinolynol, pyromethene complexes and rare-earth complexes, polymer compounds such as polythiophene, polyphenylene and polyphenylenevinylene, organic silanes, and derivatives thereof.

Specific examples of the luminescent dopants can be mentioned as follows, but it should be noted that the present invention is not limited thereto.

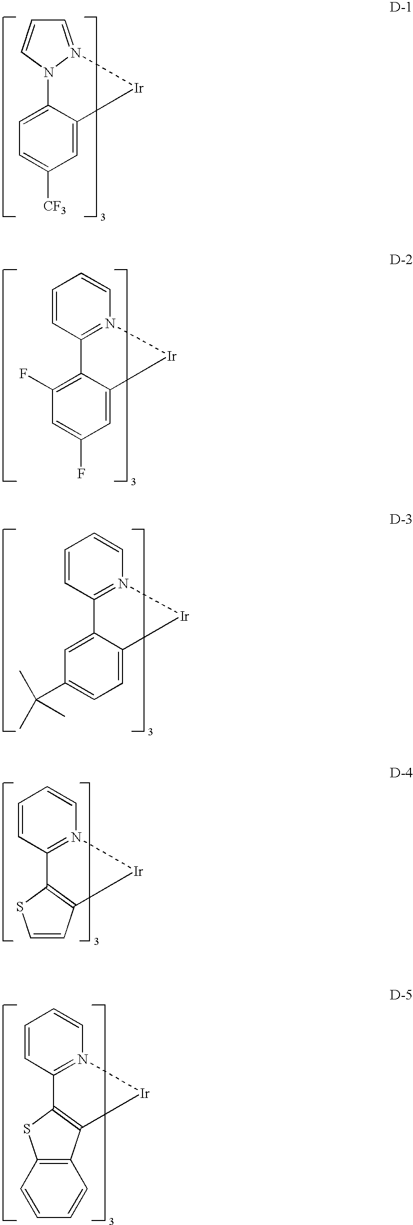

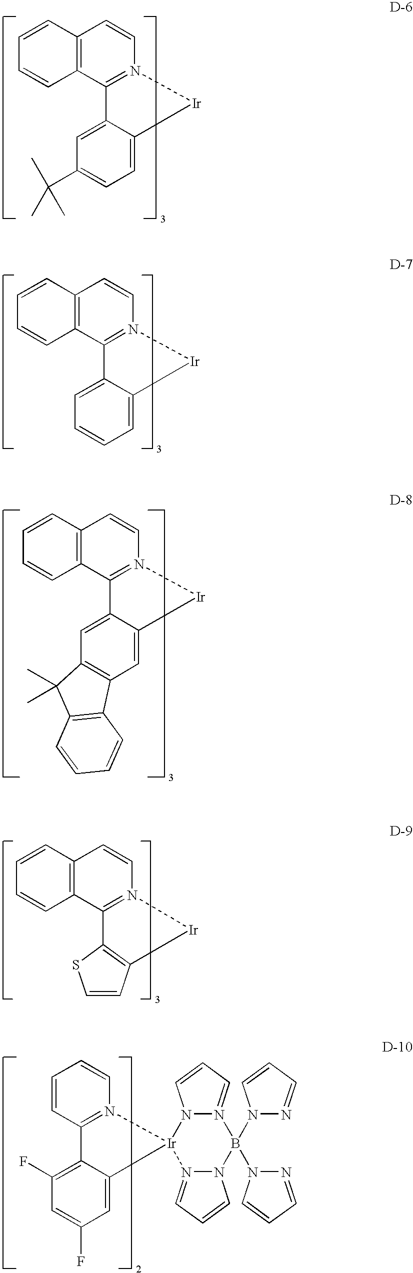

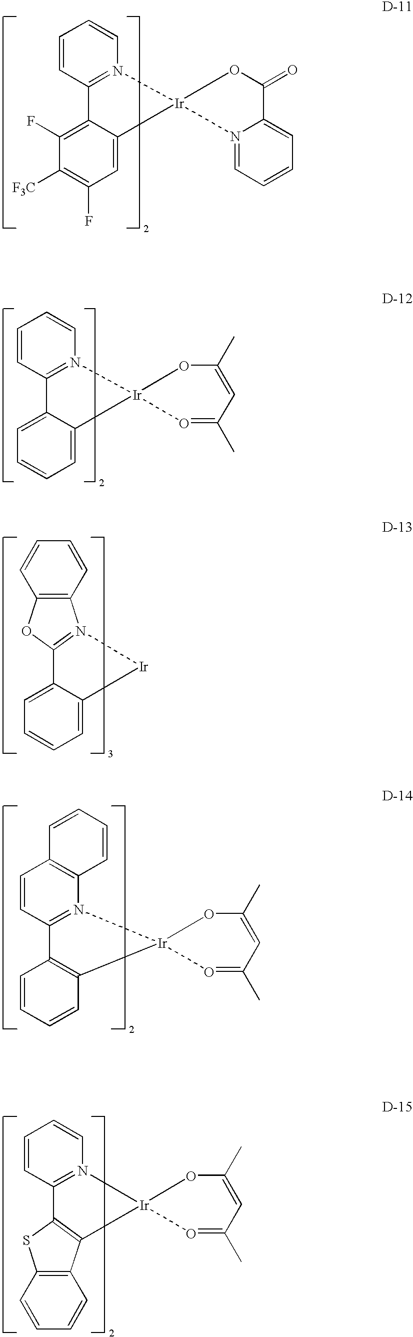

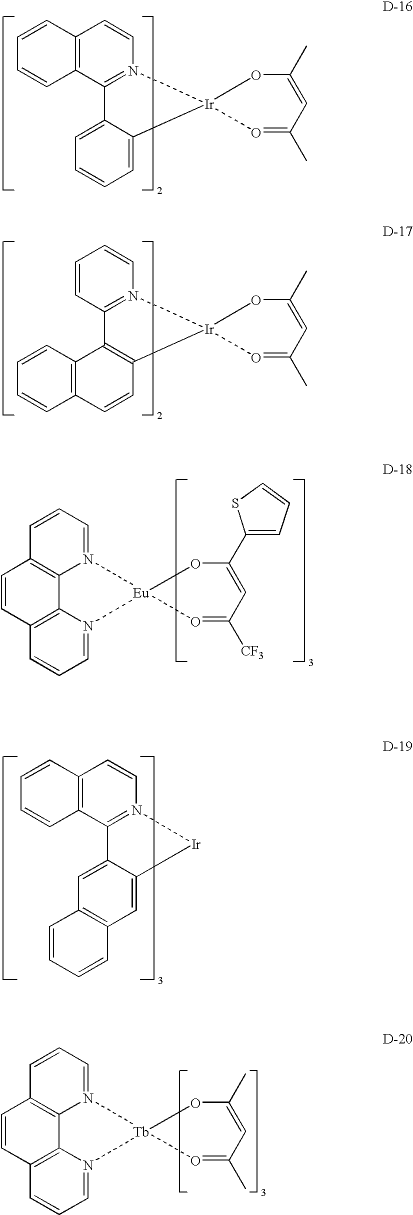

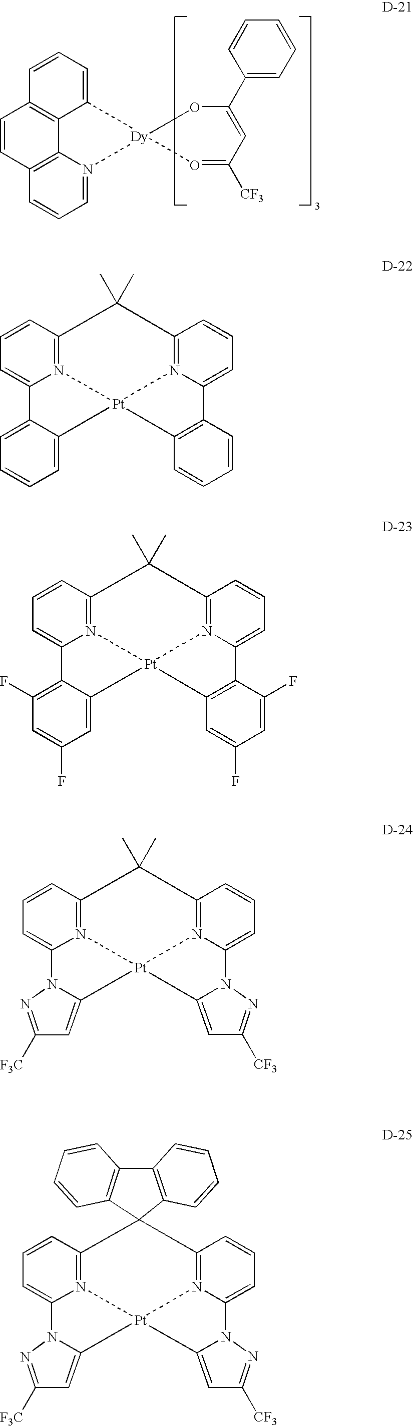

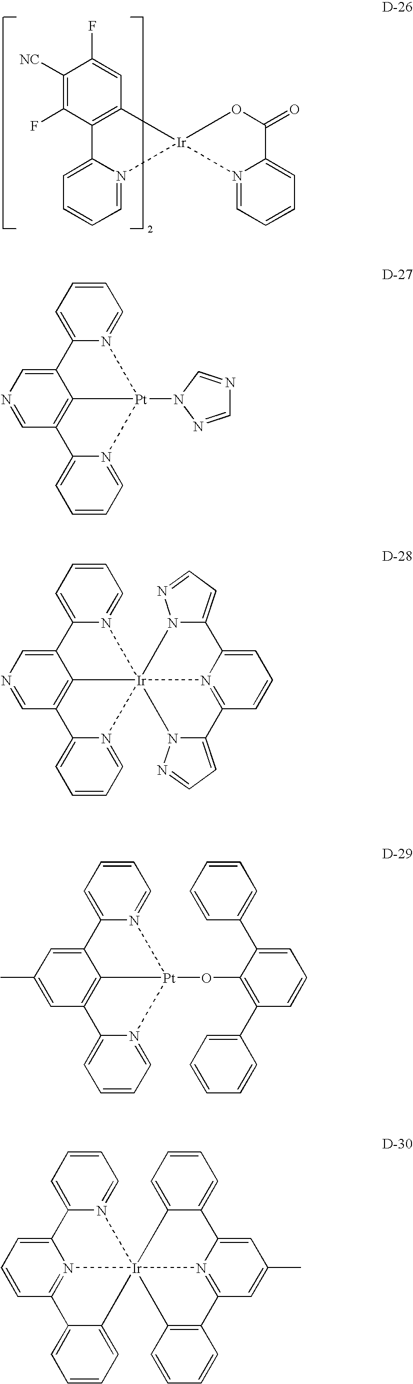

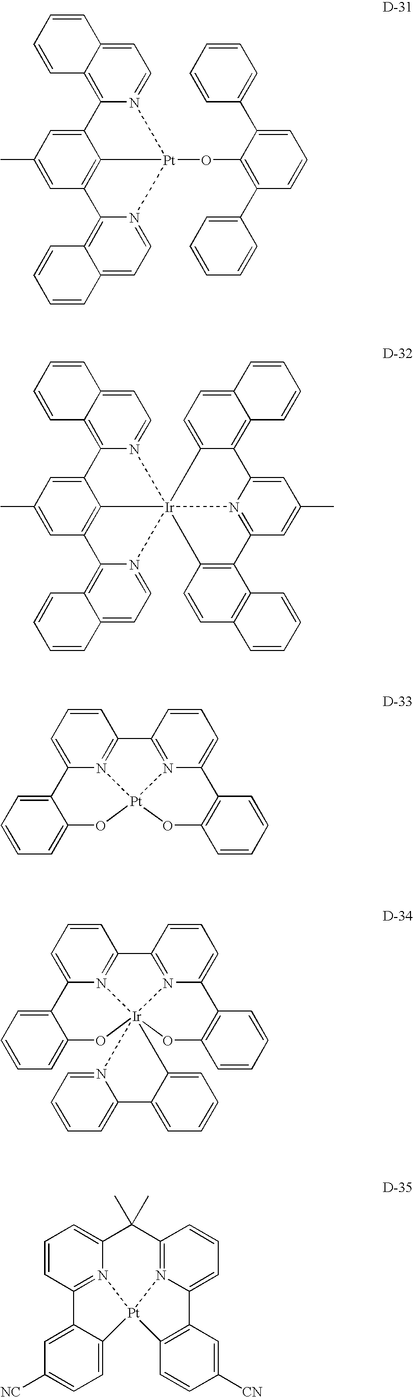

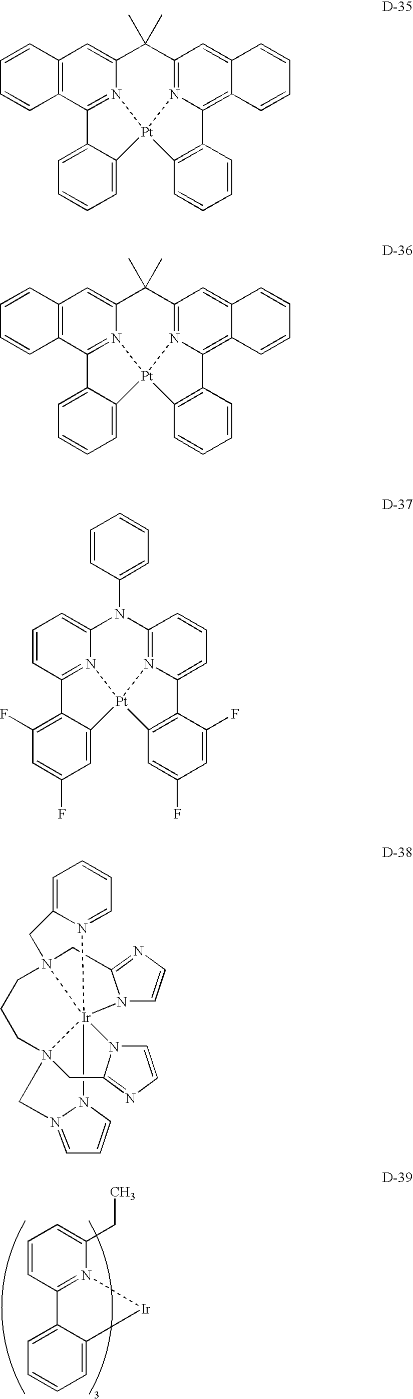

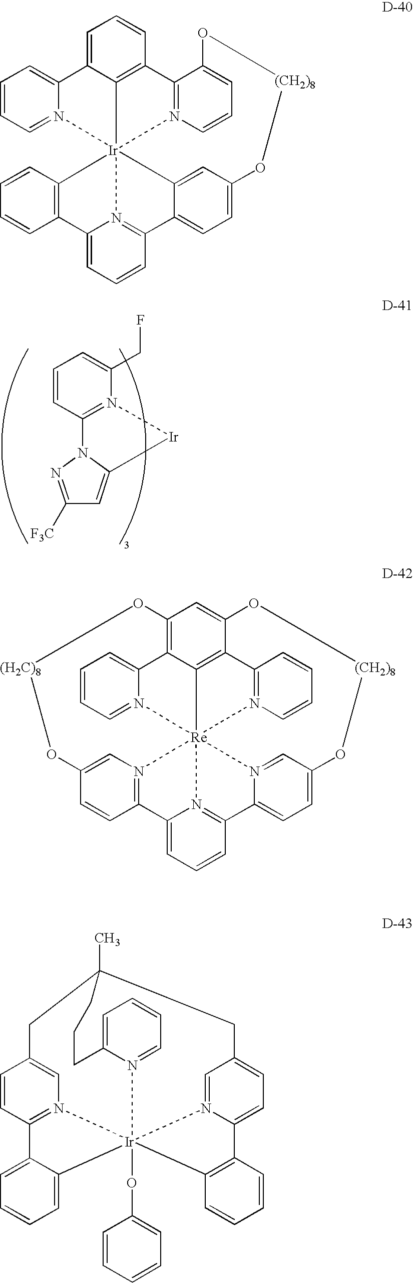

The luminescent dopant in a luminescent layer is generally contained in an amount of 0.1% by mass to 50% by mass with respect to the total mass of the compounds forming the luminescent layer, but it is preferably contained in an amount of 1% by mass to 50% by mass, and more preferably in an amount of 2% by mass to 40% by mass, in view of durability and external quantum efficiency.

Although a thickness of the luminescent layer is not particularly limited, 2 nm to 500 nm is usually preferred, wherein 3 nm to 200 nm is more preferable, and 5 nm to 100 nm is further preferred in view of external quantum efficiency efficiency.

(Host Material)

As the host material to be used according to the present invention, electron hole transporting host materials having an excellent electron hole transporting property (hereinafter, referred to as an “electron hole transporting host” in some cases) and electron transporting host compounds having an excellent electron transporting property (hereinafter, referred to as an “electron transporting host” in some cases) may be used.

<Hole Transporting Host>

Specific examples of the hole transporting hosts include pyrrole, indole, carbazole, azaindole, azacarbazole, triazole, oxazole, oxadiazole, pyrazole, imidazole, thiophene, polyarylalkanes, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidene compounds, porphyrin compounds, polysilane compounds, poly(N-vinylcarbazole), aniline copolymers, electroconductive high-molecular oligomers such as thiophene oligomers, polythiophenes and the like, organic silanes, carbon films, derivatives thereof, and the like.

Among these, indole derivatives, carbazole derivatives, aromatic tertiary amine compounds, and thiophene derivatives are preferable, more preferably a compound having a carbazole group in a molecular, and particularly preferably a compound having a t-butyl-substituted carbazole group in a molecular.

<Electron Transporting Host>

The electron transporting host used in the present invention preferably has an electron affinity (Ea) of 2.5 eV to 3.5 eV, more preferably 2.6 eV to 3.4 eV, and further preferably 2.8 eV to 3.3 eV in view of improvements in durability and decrease in driving voltage. Further, the electron transporting host used in the present invention preferably has an ionization potential (Ip) of 5.7 eV to 7.5 eV, more preferably 5.8 eV to 7.0 eV, and further preferably 5.9 eV to 6.5 eV in view of improvements in durability and decrease in driving voltage.

Specific examples of the electron transporting hosts include pyridine, pyrimidine, triazine, imidazole, pyrazole, triazole, oxazole, oxadiazole, fluorenone, anthraquinodimethane, anthrone, diphenylquinone, thiopyran dioxide, carbodiimide, fluorenylidenemethane, distyrylpyradine, fluorine-substituted aromatic compounds, heterocyclic tetracarboxylic anhydrides such as naphthaleneperylene and the like, phthalocyanine, derivatives thereof that may form a condensed ring with another ring, and metal complexes represented by metal complexes of 8-quinolynol derivatives, metal phthalocyanines, and metal complexes having benzoxazole or benzothiazole as the ligand.

Preferable electron transporting hosts include metal complexes, azole derivatives (benzimidazole derivatives, imidazopyridine derivatives and the like), and azine derivatives (pyridine derivatives, pyrimidine derivatives, triazine derivatives and the like). Among these, metal complexes are preferred in the present invention in view of durability. The metal complex compound preferably has a ligand containing at least one nitrogen atom, oxygen atom, or sulfur atom to coordinate with a metal.

A metal ion in the metal complex is not particularly limited, but is preferably a beryllium ion, a magnesium ion, an aluminum ion, a gallium ion, a zinc ion, an indium ion, a tin ion, a platinum ion, or a palladium ion is preferred; more preferably a beryllium ion, an aluminum ion, a gallium ion, a zinc ion, a platinum ion, or a palladium ion; and is further preferably an aluminum ion, a zinc ion, or a palladium ion.

There are a variety of well-known ligands to be contained in the above-described metal complexes, and examples thereof can be found in “Photochemistry and Photophysics of Coordination Compounds” authored by H. Yersin, published by Springer-Verlag Company in 1987; “YUHKI KINZOKU KAGAKU—KISO TO OUYOU—(Metalorganic Chemistry—Fundamental and Application—)” authored by Akio Yamamoto, published by Shokabo Publishing Co., Ltd. in 1982, and the like.

The ligands are preferably nitrogen-containing heterocyclic ligands (those having preferably 1 to 30 carbon atoms, more preferably 2 to 20 carbon atoms, and particularly preferably 3 to 15 carbon atoms), which may be a unidentate ligand or a bi- or higher-dentate ligand, and are preferably bi- to hexa-dentate ligands. Mixed ligands of bi- to hexa-dentate ligands with a unidentate ligand are also preferable.

Examples of the ligands include azine ligands (e.g. pyridine ligands, bipyridyl ligands, terpyridine ligands and the like), hydroxyphenylazole ligands (e.g. hydroxyphenylbenzimidazole ligands, hydroxyphenylbenzoxazole ligands, hydroxyphenylimidazole ligands, hydroxyphenylimidazopyridine ligands and the like), alkoxy ligands (those having preferably 1 to 30 carbon atoms, more preferably 1 to 20 carbon atoms, and particularly preferably 1 to 10 carbon atoms, such as methoxy, ethoxy, butoxy, 2-ethylhexyloxy and the like), aryloxy ligands (those having preferably 6 to 30 carbon atoms, more preferably 6 to 20 carbon atoms, and particularly preferably 6 to 12 carbon atoms, such as phenyloxy, 1-naphthyloxy, 2-naphthyloxy, 2,4,6-trimethylphenyloxy, 4-biphenyloxy and the like),

heteroaryloxy ligands (those having preferably 1 to 30 carbon atoms, more preferably 1 to 20 carbon atoms, and particularly preferably 1 to 12 carbon atoms, such as pyridyloxy, pyrazyloxy, pyrimidyloxy, quinolyloxy and the like), alkylthio ligands (those having preferably 1 to 30 carbon atoms, more preferably 1 to 20 carbon atoms, and particularly preferably 1 to 12 carbon atoms, such as methylthio, ethylthio and the like), arylthio ligands (those having preferably 6 to 30 carbon atoms, more preferably 6 to 20 carbon atoms, and particularly preferably 6 to 12 carbon atoms, such as phenylthio and the like), heteroarylthio ligands (those having preferably 1 to 30 carbon atoms, more preferably 1 to 20 carbon atoms, and particularly preferably 1 to 12 carbon atoms, such as pyridylthio, 2-benzimidazolylthio, benzooxazolylthio, 2-benzothiazolylthio and the like), siloxy ligands (those having preferably 1 to 30 carbon atoms, more preferably 3 to 25 carbon atoms, and particularly preferably 6 to 20 carbon atoms, such as a triphenylsiloxy group, a triethoxysiloxy group, a triisopropylsiloxy group and the like), aromatic hydrocarbon anion ligands (those having preferably 6 to 30 carbon atoms, more preferably 6 to 25 carbon atoms, and particularly preferably 6 to 20 carbon atoms, such as a phenyl anion, a naphthyl anion, an anthranyl anion and the like), aromatic heterocyclic anion ligands (those having preferably 1 to 30 carbon atoms, more preferably 2 to 25 carbon atoms, and particularly preferably 2 to 20 carbon atoms, such as a pyrrole anion, a pyrazole anion, a triazole anion, an oxazole anion, a benzoxazole anion, a thiazole anion, a benzothiazole anion, a thiophene anion, a benzothiophene anion and the like), and indolenine anion ligands. Among these, nitrogen-containing heterocyclic ligands, aryloxy ligands, heteroaryloxy ligands, siloxy ligands, aromatic hydrocarbon anion ligands and aromatic heterocyclic anion ligands are preferable, and nitrogen-containing heterocyclic ligands, aryloxy ligands, siloxy ligands, aromatic hydrocarbon anion ligands, or aromatic heterocyclic anion ligands are more preferable.

Examples of the metal complex electron transporting hosts include those described, for example, in JP-A Nos. 2002-235076, 2004-214179, 2004-221062, 2004-221065, 2004-221068, 2004-327313 and the like.

In the luminescent layer of the present invention, the host material preferably has a higher triplet exited state (T1) than that of the aforementioned phosphorescent material, from the viewpoints of color purity, luminescence efficiency, and driving durability.

The content of the host compound in the present invention is not particularly limited, and is preferably 15% by mass to 95% by mass with respect to the total mass of the compounds forming the luminescent layer in view of luminescence efficiency and driving voltage.

(Hole Injection Layer and Hole Transport Layer)

The hole injection layer and hole transport layer function to receive electron holes from the cathode or the cathode side, and transport the electron holes to the anode side. The hole-injection material and hole-transport material used for these layers may be a low molecular compound or a high molecular compound.

Specifically, the layers preferably contain pyrrole derivatives, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted calcon derivatives, styrylanthracene derivatives, fluorenone derivatives, hydrazone derivatives, stilbene derivatives, silazane derivatives, aromatic tertiary amine compounds, styrylamine derivatives, aromatic dimethylidine compounds, phthalocyanine compounds, porphyrin compounds, thiophene derivatives, organosilane derivatives, carbon, and the like.

The hole injection layer and the hole transport layer in the present invention preferably contain an electron-accepting dopant. The electron-accepting dopant may be an inorganic compound or an organic compound, as long as the compound is electron-acceptive and has a property of oxidizing an organic compound.

Specific examples of the inorganic compounds include halogenated metals such as ferric chloride, aluminum chloride, gallium chloride, indium chloride, antimony pentachloride and the like, and metal oxides such as vanadium pentaoxide, molybdenum trioxide and the like.

As the organic compounds, compounds having a substituent such as a nitro group, a halogen, a cyano group, a trifluoromethyl group and the like, quinone compounds, acid anhydride compounds, fullerenes, and the like may be preferably employed.

Another specific examples of the organic compounds include compounds described in patent documents such as JP-A Nos. 6-212153, 11-111463, 11-251067. 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643, and the like.

Among these, hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, 1,2,4,5-tetracyanobenzene, 1,4-dicyanotetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine, and fullerene C60 are preferable; hexacyanobutadiene, hexacyanobenzene, tetracyanoethylene, tetracyanoquinodimethane, tetrafluorotetracyanoquinodimethane, p-fluoranil, p-chloranil, p-bromanil, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone, and 2,3,5,6-tetracyanopyridine are more preferable; and tetrafluorotetracyanoquinodimethane is particularly preferred.

These electron-accepting dopants may be used alone or in combination of two or more of them. The amount of the electron-accepting dopant depends on the type of material, but is preferably 0.01% by mass to 50% by mass, more preferably 0.05% by mass to 20% by mass, and is particularly preferably 0.1% by mass to 10% by mass, with respect to the amount of the material for the hole transport layer.

The thicknesses of the hole injection layer and the hole transport layer are preferably 500 nm or less, respectively, in view of reducing the driving voltage.

The thickness of the hole transport layer is preferably 1 nm to 500 nm, more preferably 5 nm to 200 nm, and still more preferably 10 nm to 100 nm. The thickness of the hole injection layer is preferably 0.1 nm to 200 nm, more preferably 0.5 nm to 100 nm, and is still more preferably 1 nm to 100 nm.

The hole injection layer and the hole transport layer may have a monolayer structure comprising one or more of the above-mentioned materials, or a multilayer structure composed of plural layers having the same or different compositions.

(Electron Injection Layer and Electron Transport Layer)

The electron injection layer and the electron transport layer function to receive electrons from the cathode or the cathode side, and transport the electrons to the anode side. The electron-injection material and electron-transport material used for these layers may be a low molecular compound or a high molecular compound.

Specifically, these layers are preferably those containing a pyridine derivative, a quinoline derivative, a pyrimidine derivative, a pyrazine derivative, a phthalazine derivative, a phenanthroline derivative, a triazine derivative, a triazole derivative, an oxazole derivative, an oxadiazole derivative, an imidazole derivative, a fluorenone derivative, an anthraquinodimethane derivative, an anthrone derivative, a diphenylquinone derivative, a thiopyran dioxide derivative, a carbodiimide derivative, a fluorenylidenemethane derivative, a distyrylpyrazine derivative, an aromatic tetracarboxylic anhydride such as naphthalene and perylene, a phthalocyanine derivative, metal complexes typically represented by a metal complex of a 8-quinolinol derivative or a metal phthalocyanine, a metal complex containing benzoxazole or benzothiazole as a ligand, or an organic silane derivative typically represented by silole.

The electron injection layer and the electron transport layer in the present invention may include an electron-donating dopant. As the electron-donating dopant to be introduced in the electron injection layer or the electron-transport layer, any materials may be used as long as it has a property of donating electrons and a property of reducing an organic compound, and preferable examples thereof include alkali metals such as Li, alkaline earth metals such as Mg, transition metals including rare-earth metals, reductive organic compounds, and the like. Preferable examples of the metals include those having a work function of 4.2 V or less, and specific examples thereof include Li, Na, K, Be, Mg, Ca, Sr, Ba, Y, Cs, La, Sm, Gd, and Yb. Examples of the reductive organic compounds include a nitrogen-containing compound, a sulfur-containing compound, a phosphorus-containing compound and the like.

In addition, materials described in JP-A Nos. 6-212153, 2000-196140, 2003-68468, 2003-229278 and 2004-342614 may also be employed.

These electron-donating dopants may be used alone or in combination of two or more of them. The amount of the electron-donating dopants depends on the types of the material, but is preferably 0.1% by mass to 99% by mass, more preferably 1.0% by mass to 80% by mass, and is particularly preferably 2.0% by mass to 70% by mass, with respect to the amount of the material for the electron-transport layer.

The thicknesses of the electron injection layer and the electron transport layer are preferably 500 nm or less, respectively, in view of reducing the driving voltage. The thickness of the electron-transport layer is preferably 1 nm to 500 nm, more preferably 5 nm to 200 nm, and is particularly preferably 10 nm to 100 nm. The thickness of the electron-injection layer is preferably 0.1 nm to 200 nm, more preferably 0.2 nm to 100 nm, and is particularly preferably 0.5 nm to 50 nm.

The electron injection layer and the electron transport layer may have a monolayer structure comprising one or more of the above-mentioned materials, or a multilayer structure composed of plural layers having the same or different compositions.

(Hole Blocking Layer)

A hole blocking layer functions to block the electron holes that have been transported from the anode to the luminescent layer from passing through to the cathode side. In the present invention, a hole blocking layer may be provided as an organic compound layer that is in contact with the luminescent layer at the cathode side.

The compound that constitutes the hole blocking layer is not particularly limited, and aluminum complexes such as BAlq, triazole derivatives, phenanthroline derivatives such as BCP, and the like, can be mentioned.

The thickness of the hole blocking layer is preferably 1 nm to 500 nm, more preferably 5 nm to 200 nm, and is further preferably 10 nm to 100 nm.

The hole blocking layer may have a monolayer structure comprising one or more of the above-mentioned materials, or a multilayer structure composed of plural layers having the same or different compositions.

(Electron Blocking Layer)

An electron blocking layer functions to block the electrons that have been transported from the cathode to the luminescent layer from passing through to the anode side. In the present invention, an electron blocking layer may be provided as an organic compound layer that is in contact with the luminescent layer at the anode side.

Specific examples of the compounds that may constitute the electron blocking layer include the above-mentioned compounds for the hole transporting material.

The thickness of the electron blocking layer is preferably 1 nm to 500 nm, more preferably 5 nm to 200 nm, and is further preferably 10 nm to 100 nm.

The electron blocking layer may have a monolayer structure comprising one or more of the above-mentioned materials, or a multilayer structure composed of plural layers having the same or different compositions.

(Protective Layer)

In the present invention, the entire organic EL element may be protected by a protective layer.

The material contained in the protective layer may be any ones at least they have a function to prevent the substances such as moisture and oxygen, which can accelerate deterioration of the device, from penetrating into the device.

Specific examples of the materials include metals such as In, Sn, Pb, Au, Cu, Ag, Al, Ti, Ni and the like; metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polymers such as polyethylene, polypropylene, polymethylmethacrylate, polyimide, polyurea, polytetrafluoroethylene, polychlorotrifluoroethylene, polydichlorodifluoroethylene, copolymers of chlorotrifluoroethylene and dichlorodifluoroethylene, copolymers obtained by copolymerizing a monomer mixture containing tetrafluoroethylene and at least one comonomer, fluorine-containing copolymers each having a cyclic structure in the copolymerization main chain; water absorbing materials having a water absorption of 1% or more; moisture proofing materials having a water absorption of 0.1% or less; and the like.

The method for forming the protective layer is not particularly limited, and applicable examples thereof include a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD method, a laser CVD method, a thermal CVD method, a gas source CVD method, a coating method, a printing method, and a transfer method.

(Sealing)

The entire organic EL element of the present invention may be sealed with a sealing cap.

Furthermore, a moisture absorbent or an inert liquid may be contained in a space between the sealing cap and the luminescent device. The moisture absorbent is not particularly limited and specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide and the like. The inert liquid is not particularly limited and specific examples thereof include paraffins, liquid paraffins, fluorine-based solvents such as perfluoroalkanes, perfluoroamines, perfluoroethers and the like, chlorine-based solvents, silicone oils, and the like.

A resin sealing layer described below may also be favorably employed for sealing. The functional device of the present invention is preferably prevented from deteriorating due to contact with air, oxygen or moisture, by means of the resin sealing layer.

<Material>

The resin material for the resin sealing layer is not particularly limited, and specific examples thereof include acrylic resins, epoxy resins, fluorocarbon resins, silicone resins, rubber resins, and ester resins. Among these, epoxy resins are preferable in view of moisture prevention. Among the epoxy resins, heat-curable or photo-curable epoxy resins are most preferable.

<Preparation Method>

The method for preparing the resin sealing layer is not particularly limited and examples thereof include a method of applying a resin solution; a method of bonding a resin sheet with pressure or heat; and a method of dry-polymerizing by vapor deposition, sputtering or the like.

<Layer Thickness>

The thickness of the resin sealing layer is preferably 1 μm to 1 mm, more preferably 5 μm to 100 μm, and is particularly preferably 10 μm to 50 μm. When the thickness is less than the above range, the aforementioned inorganic film may be damaged upon mounting of the second substrate. When the thickness is more than the above range, the thickness of the EL element may be increased, thereby degrading the slimness which is characteristic of organic EL elements.

(Sealing Adhesive)

The sealing adhesive used in the present invention has a function to prevent penetration of moisture or oxygen from the edges of the organic EL element.

<Material>

The material for the sealing adhesive may be the aforementioned materials for the resin sealing layer. Among these, epoxy adhesives are preferable in view of moisture prevention, and photo-curable or heat-curable ones are most preferable.

Further, a filler may be added to the material. The filler to be added to the sealing adhesive is preferably inorganic materials such as SiO₂, SiO, SiON and SiN. By adding a filler, the viscosity of the sealing adhesive can be increased, and processability and moisture resistance can be improved.

<Drying Agent>

The sealing agent may contain a drying agent. Preferable examples thereof include barium oxide, calcium oxide and strontium oxide. The addition amount of the drying agent to the sealing adhesive is preferably 0.01% to 20% by mass, and is more preferably 0.05% to 15% by mass. When the amount is less than the above range, the effect of adding the drying agent may be decreased. When the amount is more than the above range, it may be difficult to uniformly disperse the drying agent into the sealing adhesive.

<Formulation of Sealing Adhesive>

The polymer composition and concentration of the sealing agent is not particularly limited, and the aforementioned ones may be employed. For example, a photo-curable epoxy adhesive XNR5516 (trade name, manufactured by Nagase chemteX Corporation) can be mentioned. The sealing adhesive can be prepared by adding a drying agent directly to the adhesive and allow to disperse.

The application thickness of the sealing adhesive is preferably 1 μm to 1 mm. When the thickness is less than the above range, the sealing adhesive may not be uniformly applied. When the thickness of the sealing adhesive is more than the above range, the path for moisture to penetrate may be widened.

<Sealing Process>

In the present invention, a functional device can be obtained by applying an appropriate amount of the sealing adhesive containing the aforementioned drying agent onto the device by a dispenser and the like; laminating the second substrate; and curing the resultant.

(Driving)

In the organic EL element of the present invention, luminescence can be obtained by applying a DC voltage (AC components may be contained as needed) of usually 2 volts to 15 volts, or a DC electricity across the anode and the cathode.

For the driving method of the organic EL element of the present invention, driving methods described in JP-A Nos. 2-148687, 6-301355, 5-29080, 7-134558, 8-234685, and 8-241047; Japanese Patent No. 2784615, U.S. Pat. Nos. 5,828,429 and 6,023,308, and the like, are applicable.

In the organic EL element of the present invention, the light-extraction efficiency can be improved by various known methods. For example, the light-extraction efficiency and the external quantum efficiency can be improved by modifying the surface texture of the substrate (by forming fine irregularity patterns and the like); controlling the refractive index of the substrate, ITO layer and/or organic layer; or by controlling the thickness of the substrate, ITO layer and/or organic layer.

The organic EL element of the present invention may have a so-called top-emission configuration in which light is extracted from the anode side.

In order to enhance the light emission efficiency, the organic EL element of the invention may have a configuration that a charge generating layer is provided between plural luminescent layers. The charge generating layer has functions to generate charges (holes and electrons) upon application of an electric field and to inject the generated charges into a layer adjacent to the charge generating layer.

Materials that constitutes the charge generating layer may be any materials that exert the above functions, and the layer may be formed from a single compound or plural compounds.

Specifically, the compound may be a conductive material or a semiconductive material such as a doped organic layer, and further, may be an electrical insulating material. Examples thereof include those disclosed in JP-A Nos. 11-329748, 2003-272860 and 2004-39617.

More specifically, transparent conductive materials such as ITO, IZO (indium zinc oxide) and the like, conductive organic substances such as C60 fullerenes, oligothiophenes and the like, conductive organic substances such as metal phthalocyanines, phthalocyanines without metal, metal porphyrins, porphyrins without metal, metal materials such as Ca, Ag, Al, Mg:Ag alloys, Al:Li alloys, hole conductive materials, electron conductive materials, and mixtures thereof may be used.

The hole conductive materials may be, for example, those obtained by doping an electron attractive oxidant such as F4-TCNQ, TCNQ, FeCl₃ or the like into a hole transport organic material such as 2-TNATA, NPD or the like, p-type conductive polymers, and p-type semiconductors. The electron conductive materials may be, for example, those obtained by doping a metal or metal compound having a work function of lower than 4.0 eV into an electron transport organic material, n-type conductive polymers, and n-type semiconductors. As the n-type semiconductors, n-type Si, n-type CdS, n-type ZnS and the like can be mentioned. As the p-type semiconductors, p-type Si, p-type CdTe, p-type CuO and the like can be mentioned. Further, as the aforementioned charge generating layer, an electric insulating material such as V₂O₅ and the like may be used.

The charge generating layer may have a monolayer structure or a multilayer structure. Example of the multilayer configurations include a lamination structure including a layer of a conductive material such as a transparent conductive material or metal material and a layer of a hole conductive material or an electron conductive material; and a lamination structure including a layer of a hole conductive material and a layer of an electron conductive material.

In general, the thickness and material of the charge generating layer are preferably selected so that the charge generating layer has a visible light transmittance of 50% or more. The layer thickness is not specifically limited, but is preferably from 0.5 nm to 200 nm, more preferably from 1 nm to 100 nm, further more preferably from 3 nm to 50 nm, and most preferably from 5 nm to 30 nm.

The method of forming the charge generating layer is not specifically limited, and the aforementioned methods of forming the organic compound layer can be applied.

The charge generating layer is formed between two or more luminescent layers, and may contain a material having a function of injecting charges to a layer adjacent to the charge generating layer at the anode side and the cathode side thereof. In order to increase the property of injecting electrons to the layer adjacent to the anode side, for example, an electron injecting compound such as BaO, SrO, Li₂O, LiCl, LiF, MgF₂, MgO or CaF₂ may be deposited at the anode side of the charge generating layer.

In addition to the above, materials for the charge generating layer may be selected on the basis of the descriptions of JP-A No. 2003-45676, U.S. Pat. Nos. 6,337,492, 6,107,734 and 6,872,472.

The organic EL element in the invention may have a resonator structure. In a first exemplary embodiment of the resonator structure, on a transparent substrate, a multilayer mirror composed of laminated plural layers having different refractive indexes, a transparent or translucent electrode, a luminescent layer and a metal electrode are laminated. The light generated in the luminescent layer is repeatedly reflected between the multilayer mirror and the metal electrode serving as reflection plates to be resonated.

In a second exemplary embodiment, the transparent or translucent electrode and the metal electrode each function as a reflecting plate, on the transparent substrate, and the light generated in the luminescent layer is repeatedly reflected therebetween to be resonated.

In order to form a resonator structure, the length of optical path determined by effective refractive indexes of the two reflecting plates, the refractive index and thickness of each layer between the reflecting plates is adjusted to an optimal value for obtaining a desired resonating wavelength. The calculation formula for the above first embodiment is described in JP-A No. 9-180883, and the calculation formula for the above second embodiment is described in JP-A No. 2004-127795.

As the methods of producing a full-color type organic EL display, there have been known, for example, as described in “Monthly Display”, September, 2000, pp. 33-37, a three color luminescent method in which organic EL elements emitting lights corresponding to the primary three colors (blue (B), green (G) and red (R)), respectively, are arrayed on a substrate; a white color method in which white light emitted from a white luminescent organic EL element is separated into three primary colors through color filters; and a color conversion method in which blue light emitted from a blue luminescent organic EL element is converted into red (R) and green (G) through fluorescent color layers.

Further, by employing two or more of organic EL elements that emit light of different colors obtained by the above methods in combination, a flat panel light source having desired colors of emitted light can be obtained. For example, a white color emitting light source obtained by combining a blue luminescent element with a yellow luminescent element, and a white color emitting light source obtained by combining a blue luminescent element, a green luminescent element and a red luminescent element, can be mentioned.

### 3. Configuration of Organic EL Display Device

The organic EL display device of the present invention includes at least an organic EL element and a drive TFT that supplies an electric current to the organic EL element.

In the present invention, the substrate of the organic El display device preferably serves also as the substrate of the drive TFT, and more preferably, the substrate is a flexible resin substrate.

Preferably, the source electrode or the drain electrode of the drive TFT and the electrode of the organic EL element, for example the anode, are made of the same material and are formed in the same process.

Preferably, the source electrode or the drain electrode and the pixel electrode of the organic EL element are formed from indium tin oxide.

Preferably, an insulation film is formed on the periphery of the pixel electrode of the organic EL element. More preferably, the insulation film and an insulation film of the drive TFT are formed from the same material and are formed in the same process.

Accordingly, the organic EL element and the drive TFT of the invention preferably have a part of the components being formed from the same material and formed in the same process, whereby the production process thereof can be simplified and the production cost can be reduced.

Hereinafter, the configuration and production process of the organic EL display device of the present invention will be described with reference to the drawings.

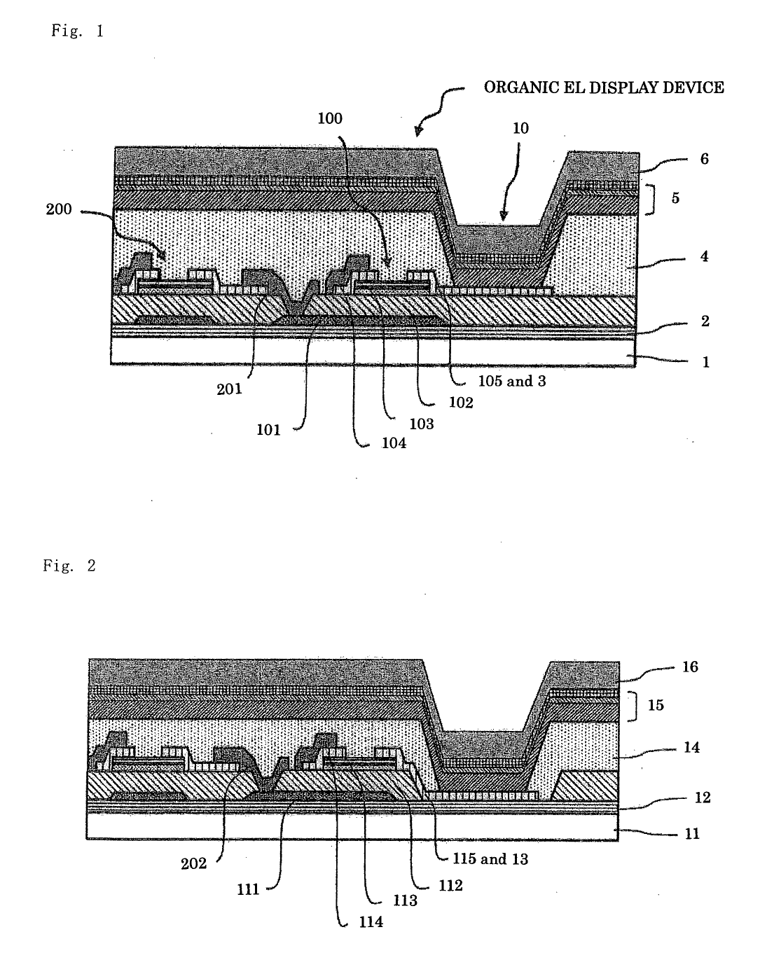

FIG. 1 is a conceptual drawing showing a drive TFT 100 and an organic EL element 10 of the invention. A substrate 1 is a flexible support of a plastic film such as PEN, and has, on the surface of the substrate, a substrate insulation film 2 for preventing penetration of water vapor, oxygen and the like. On the surface of the insulation film 2, a gate electrode 101 is provided at the portions corresponding to the drive TFT 100 and a switching TFT portion 200. A gate insulation film 102 is further provided in order to cover the area corresponding to the TFTs and the whole organic EL element. A contact hole is provided at a part of the gate insulation film 102 for electrical connection. An active layer and a resistive layer of the invention 103 are provided at the drive TFT portion and the switching TFT portion, and a source electrode 105 and a drain electrode 104 are disposed on the active layer. The source electrode 105 and a pixel electrode (anode) 3 of the organic EL element 10 are integral with each other, and are formed from the same material in the same process. The drain electrode of the switching TFT 200 and the gate electrode 101 are electrically connected via a connection electrode 201 at the contact hole. The whole area is covered with an insulation film 4 except for the pixel electrode portion onto which the organic EL element is formed. An organic layer 5 including a luminescent layer and an upper electrode (cathode) 6 are formed on the pixel electrode portion, and thus the organic EL element 10 is formed.

FIG. 2 is a conceptual drawing illustrating another configuration of a drive TFT and an organic EL element of the organic EL display device of the present invention. A substrate 11 is a flexible support of a plastic film such as PEN, and has, on the surface of the substrate, a substrate insulation film 12 for preventing penetration of water vapor, oxygen and the like. On the surface of the insulation film 12, a gate electrode 111 is provided at the portions corresponding to the drive TFT and a switching TFT, and further a gate insulation film 112 is provided only at the portions corresponding to the TFTs. A contact hole is provided at a part of the gate insulation film 112 for electrical connection. Active and resistive layers of the invention 113 are provided at the portions corresponding to the drive TFT and the switching TFT, and a source electrode 115 and a drain electrode 114 are disposed thereon. The source electrode 115 and a pixel electrode (anode) 13 of the organic EL element are integral with each other, and are formed from the same material in the same process. The drain electrode of the switching TFT and the gate electrode 111 are electrically connected with each other via a connection electrode 202 at the contact hole. The whole area is covered with an insulation film 14 except for the pixel electrode portion on which the organic EL element is formed. An organic layer 15 including a luminescent layer and an upper electrode (cathode) 16 are formed on the pixel electrode portion, and thus the organic EL element portion is formed.

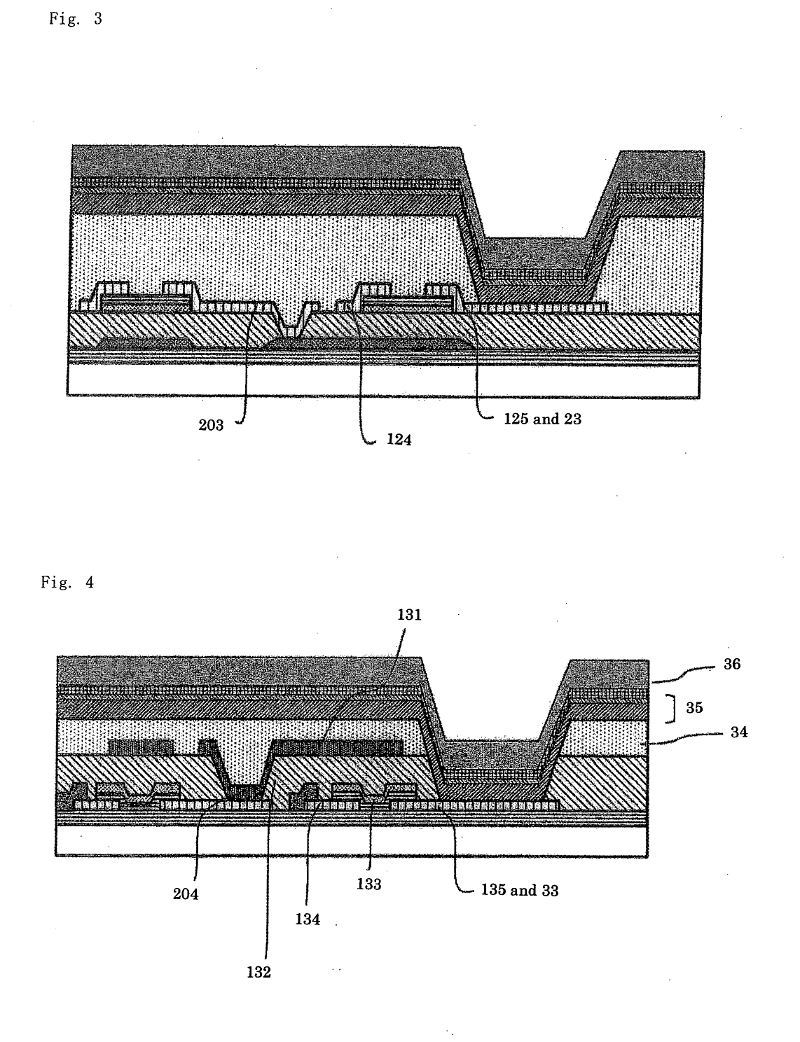

FIG. 3 is a conceptual drawing illustrating a configuration of a drive TFT and an organic EL element of another organic EL display device of the present invention. A substrate 11 is a flexible support of a plastic film such as PEN, similar to FIGS. 1 and 2, and has, on the surface of the substrate, a substrate insulation film for preventing penetration of water vapor, oxygen and the like. On the surface of the insulation film, a gate electrode is provided at the portions corresponding to the drive TFT and the switching TFT in a similar manner to FIG. 1, and further a gate insulation film is provided over the whole of the TFTs and the organic EL element. A contact hole is provided at a part of the gate insulation film for electrical connection. An active layer and a resistive layer of the invention are provided at the portions corresponding to the drive TFT and the switching TFT. A source electrode 125, a drain electrode 124, a connection electrode 203 and a pixel electrode (anode) 23 are formed from the same material in the same process. Further, the whole area is covered with an insulation film except for the pixel electrode portion on which the organic EL element is formed. An organic layer including a luminescent layer and an upper electrode (cathode) are formed on the pixel electrode portion, and thus the organic EL element portion is formed.

FIG. 4 is a conceptual drawing illustrating a configuration of a drive TFT and an organic EL element of another organic EL display device of the present invention, which is employing a top gate type TFT. A substrate is a flexible support of a plastic film such as PEN similar to FIGS. 1 and 2, and has, on the surface of the substrate, a substrate insulation film for preventing penetration of water vapor, oxygen and the like. On the surface of the insulation film, a source electrode 135, a drain electrode 134, and active and resistive layers 133 are provided. A pixel electrode 33 is formed integrally with the source electrode 135 from the same material, in the same process. A gate insulation film 132 is provided thereon so as to cover a drive TFT and a switching TFT portion, and a contact hole is provided at a part of the gate insulation film for electrical connection. A gate electrode 131 and a connection electrode 204, that are formed from the same material in the same process, are provided. Further, the whole area is covered with an insulation film 34 except for the pixel electrode portion on which the organic EL element is formed. An organic layer 35 including a luminescent layer and an upper electrode (cathode) 36 are formed on the pixel electrode portion, and thus the organic EL element is formed.

In FIGS. 1 to 4 are shown configurations in which the source electrode of the drive TFT is connected to the pixel electrode of the organic EL element. However, in another embodiment, a drain electrode of the drive TFT may be connected to a pixel electrode of the organic EL element. In the case of a configuration in which the source electrode of the drive TFT is connected to the pixel electrode of the organic EL element, the pixel electrode is preferably an anode, and in the case of a configuration in which the drain electrode of the drive TFT is connected to the pixel electrode of the organic EL element, the pixel electrode is preferably a cathode.

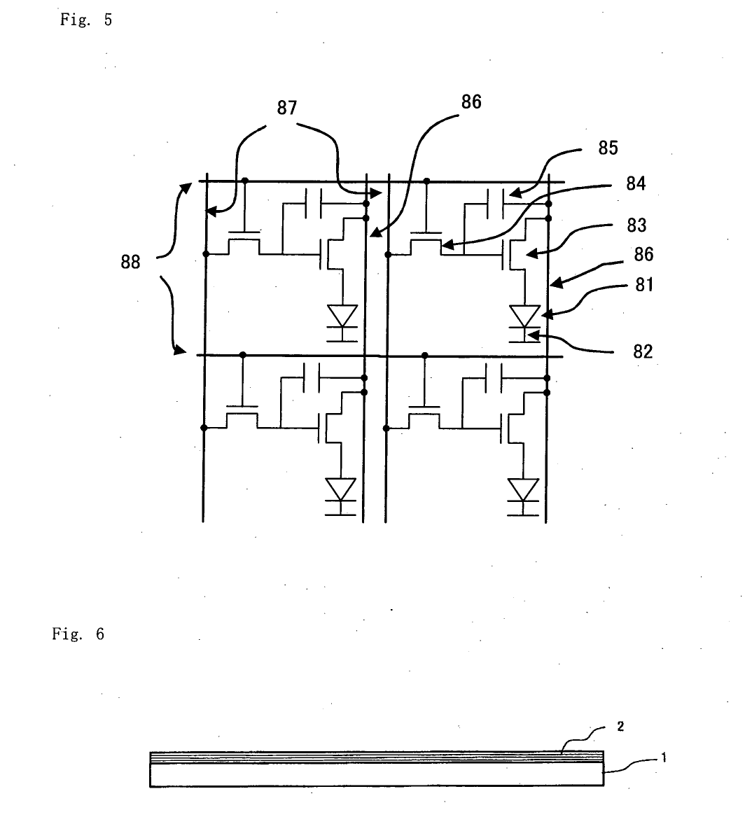

FIG. 5 is a schematic circuit diagram of the main portion of a switching TFT 84, a drive TFT 83 and an organic EL element 81 in the organic EL display device of the present invention. In FIG. 5, cathode 82, condenser 85, common wires 86, signal wires 87 and scanning wires 88 are also shown. The pixel circuit of the organic EL display device of the present invention is not particularly limited to the circuit as shown in FIG. 5, and any conventionally known pixel circuits may be applied.

In the following, the production process of the organic EL display device will be explained by referring to a manufacturing process of the organic EL display device of the invention shown in FIG. 1. Other embodiments of the organic EL display devices than that shown in FIG. 1 may also be manufactured in a similar manner.

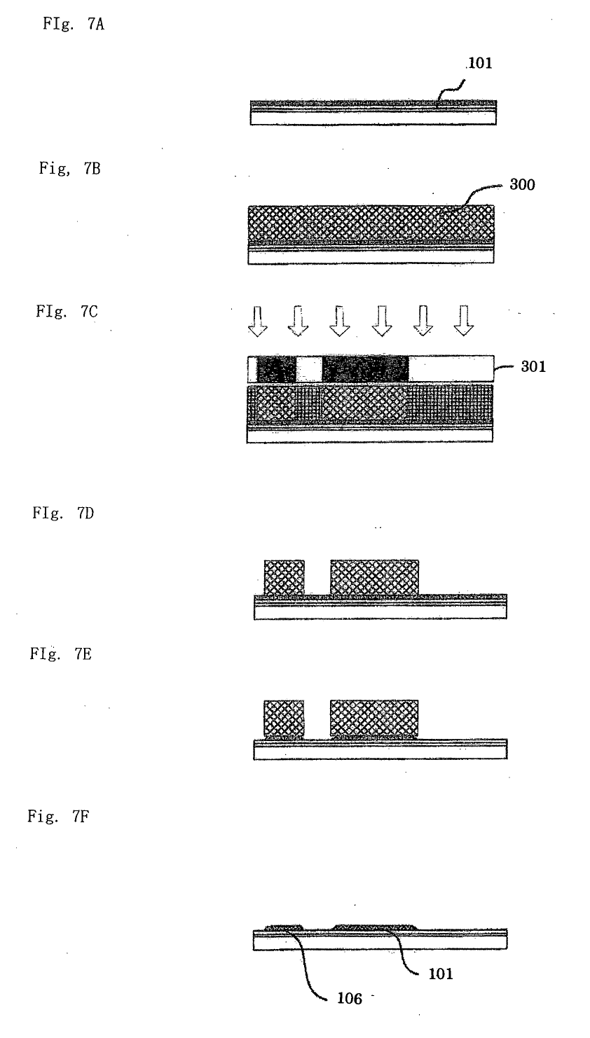

As shown in FIG. 6, a substrate insulation film 2 is deposited on a flexible substrate 1. Next, as shown in FIGS. 7A to 7F, a gate electrode 101 and scanning wiring lines are formed by the following photolithographic etching method. A gate electrode layer is formed on the substrate insulation film 2, and a photoresist 300 is applied thereon. After superposing a photomask 301 onto the photoresist and pattern-exposing to light, the photoresist is additionally heated to cure the portion thereof that has not been exposed to light. The photoresist is then immersed into an alkali developer to remove the uncured portion of the photoresist. Thereafter, an electrode etching liquid is applied onto the surface to dissolve and remove the portion with no photoresist, i.e., the portion that has been exposed to light, and therefore the gate electrode 101 and the scanning wiring lines are formed.

The above process is an example of patterning performed by using a negative work photoresist, but the patterning may also be performed by using a positive work photoresist to dissolve and remove the portion that has not been exposed to light.

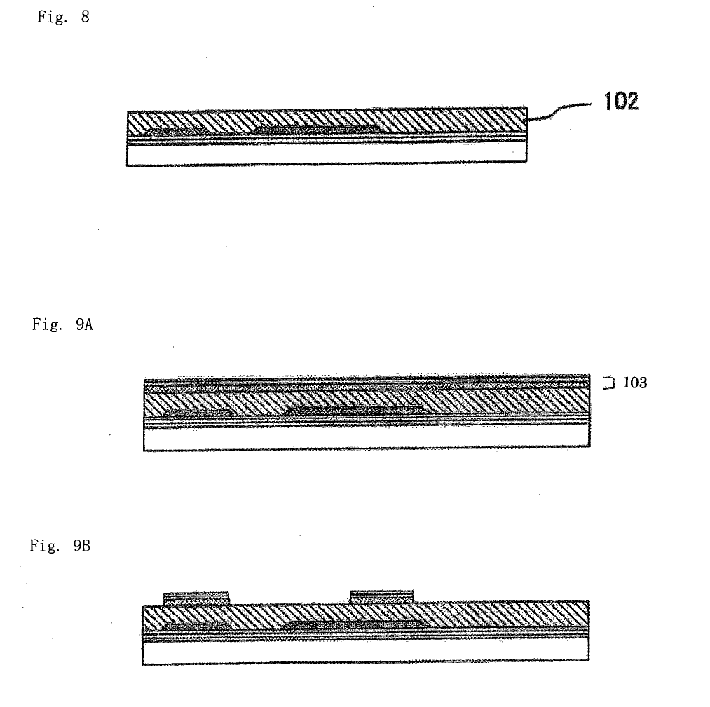

Next, a gate insulation film 102 is disposed (FIG. 8), and active and resistive layers 103 are disposed on the gate insulation film in a multilayered manner (FIG. 9A), and patterning of the active and resistive layers 103 is performed by a photolithographic etching method as explained in FIG. 7 (FIG. 9B).

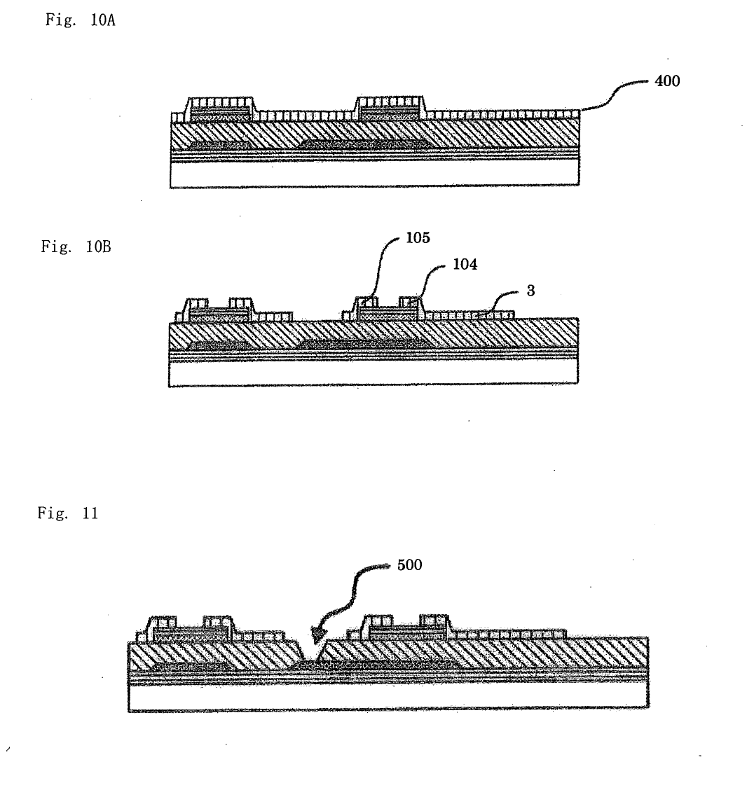

The source and drain electrodes of the drive TFT and switching TFT, and the pixel electrode of the organic EL element are formed from the same material, in the same process. First, an electrode film 400 is formed on the entire surface of the gate insulation film (FIG. 10A). Subsequently, patterning is performed in accordance with the photolithographic etching method as described above, thereby forming a source electrode and a drain electrode of the switching TFT, a source electrode 105 and a drain electrode 104 of the drive TFT, and a pixel electrode (anode) 3 of the organic EL element (FIG. 10 B).

As occasion demands, the source and drain electrodes of the driving and switching TFTs and a pixel electrode of the organic EL element may be formed by a lift-off method. The lift-off method is a technique of patterning a thin film by forming a resist on a portion where the film is not to be formed; forming a thin film by sputtering or the like; and then stripping off the resist to form a thin film pattern.

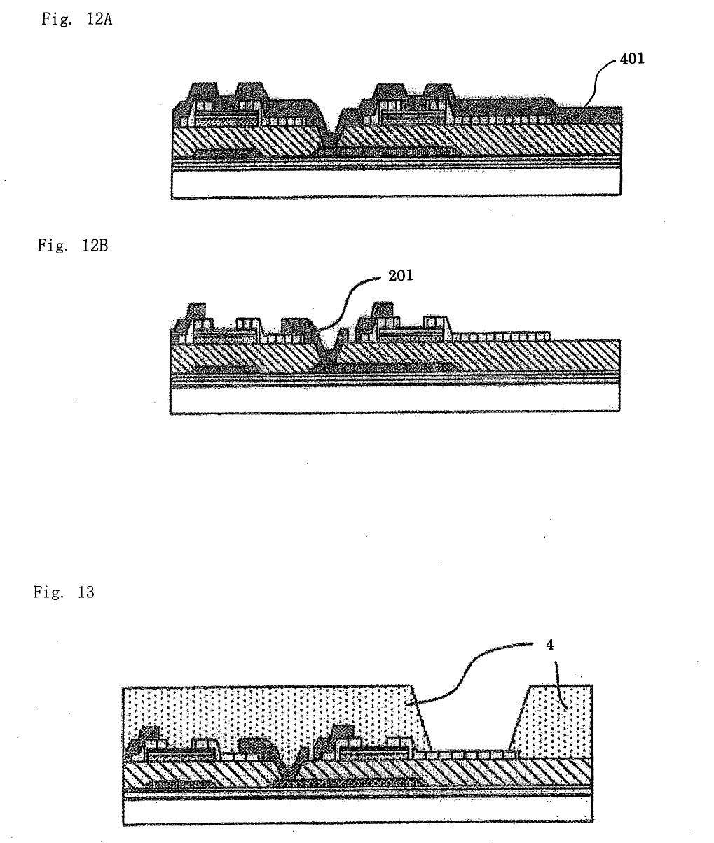

Next, a contact hole 500 is formed in the gate insulation film 102 through patterning by a photolithographic etching method (FIG. 11), and another electrode film 401 is formed thereon (FIG. 12A). A connection electrode 201 is formed through patterning by a photolithographic etching method (FIG. 12B). Subsequently, an insulation film 4 is formed on the entire surface, and a portion of the insulation film 4 where the organic EL element is formed is removed through patterning by a photolithographic etching method (FIG. 13).

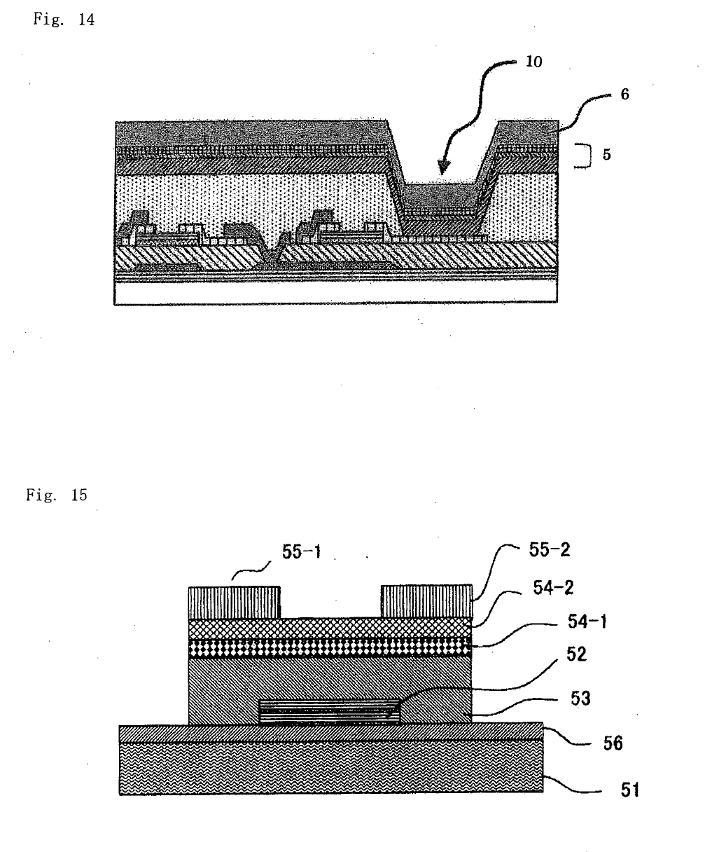

An organic layer 5 including a luminescent layer is laminated on the portion where the insulation film have been removed to expose the anode electrode and the organic EL element 10 is to be disposed, and finally, an upper electrode (cathode) 6 is formed thereon (FIG. 14).

The aforementioned production process has such advantages that the switching TFT, drive TFT and organic EL elements can be formed on the same flexible substrate; some or all of these can be formed from the same material in the same process; the source and drain electrodes of the switching and drive TFTs and the anode of the organic EL element can be formed from the same material in the same process; many of the production process can be simplified; and the risk of troubles such as imperfect electrical contact can be reduced by the reduced number of electrical contact points.

(Applications)

The organic EL display device of the invention can be applied to a wide range of fields including displays for digital still cameras, displays for mobile phones, personal digital assistants (PDA), computer displays, information displays for motor vehicles, TV monitor displays, general illumination devices, and the like.

### EXAMPLES

Hereinafter, the organic EL display device of the invention will be described by referring to the examples. However, the invention is not limited to the examples.

### Example 1

### 1. Preparation of Organic EL Display Device

An organic EL display device 1 having a configuration as shown in FIG. 1 was prepared in accordance with the following processes.

(1) Formation of Substrate Insulation Film (FIG. 6)

SiON was deposited by sputtering on a polyethylene naphthalate film (referred to as “PEN”) to a thickness of 50 nm to form a substrate insulation film.

Sputtering condition: apparatus; an RF magnetron sputtering apparatus, RF power; 400 W, sputtering gas flow rate; Ar/O₂=12.0/3.0 sccm, target; Si₃N₄.

(2) Formation of Gate Electrode (and Scanning Wiring Lines) (FIGS. 7A to 7F)

After washing the above substrate, Mo was deposited thereon by sputtering to a thickness of 100 nm. Next, a photoresist was applied thereon, and a photomask was superposed thereon. The photoresist was exposed to light through the photomask, and then heated to cure the unexposed portion of the photomask. Uncured portions were removed by treating with an alkali developer. Thereafter, an electrode etching liquid was applied onto the surface to dissolve and remove the electrode portion that was not covered with the cured photoresist. Lastly, the photoresist was stripped off to complete the patterning, and thus the patterned gate electrode 101 and scanning wire 106 were formed.

The conditions of each step of the above process were as follows:

Mo sputtering: apparatus; a DC magnetron sputtering apparatus, DC power; 380 W, sputtering gas flow rate; Ar=12.0 sccm.

Photoresist application: photoresist; OFPR-800 (manufactured by TOKTO OHKA KOGYO CO., LTD.), spin-coated at 4000 rpm for 50 sec.

Pre-baking: at 80° C. for 20 min.

Exposure: performed for 5 sec. (equivalent to 100 mJ/cm² with a g-line super high pressure mercury lamp;)

Development: developer; NMD-3800 (manufactured by TOKTO OHKA KOGYO CO., LTD.), immersed for 30 sec. and agitated for 30 sec.

Rinse: pure water ultrasonic washing for 1 min. (twice)

Post-baking: 120° C. for 30 min.

Etching: etching solution and mixed acid (nitric acid/phosphoric acid/acetic acid)

Resist stripping: stripping solution; 104 (manufactured by TOKTO OHKA KOGYO CO., LTD.), immersed for 5 min. (twice)

Washing: IPA ultrasonic wave washing for 5 min. (twice) and pure water ultrasonic wave washing for 5 min.

Drying: N₂ blowing and baking at 120° C. for 1 hour.

(3) Formation of Gate Insulation Film (FIG. 8)

Next, SiO₂ is layered by sputtering to a thickness of 200 nm to form a gate insulation film.

Sputtering condition: apparatus; an RF magnetron sputtering apparatus, RF power; 400 W, sputtering gas flow rate; Ar/O₂=12.0/2.0 sccm.

(4) Formation of Active and Resistive Layers (FIG. 9)

High electroconductive IGZO film (active layer) of 10 nm in thickness and a low electroconductive IGZO film (resistive layer) of 40 nm in thickness were sequentially layered on the gate insulation film by sputtering, and a patterning was conducted by a photoresist method to form an active layer and a resistive layer.

The sputtering conditions of the high electroconductive IGZO layer and the low electroconductive IGZO layer were as follows:

Sputtering of high electroconductive IGZO film: apparatus; an RF magnetron sputtering apparatus, RF power; 200 W, sputtering gas flow rate; Ar/O₂=12.0/0.6 sccm, target; a polycrystalline sintered body having a composition of InGaZnO₄.

Sputtering of low electroconductive IGZO film: apparatus; an RF magnetron sputtering apparatus, RF power; 200 W, sputtering gas flow rate; Ar/O₂=12.0/1.6 sccm, target; a polycrystalline sintered body having a composition of InGaZnO₄.

The films formed on quartz substrates by sputtering these IGZOs under the same conditions as above were evaluated by X ray diffraction (thin film method at an incident angle of 0.5°). The result was that no distinct diffraction peaks were detected, indicating that these IGZO films were amorphous films.

The patterning step by the photolithographic etching method was the same as the patterning step for the gate electrode except that hydrochloric acid was used as an etching solution.

(5) Formation of Source and Drain Electrodes and Pixel Electrode (FIGS. 10a and 10B)

Source and drain electrodes and a pixel electrode were formed by a lift off method. After a lift off resist has been formed, a layer of indium tin oxide (ITO) was formed to a thickness of 40 nm by sputtering, and thereafter, the resist was stripped off to form source and drain electrodes and a pixel electrode. The conditions of the lift off resist formation and the resist stripping-off were the same as the conditions for the above-described photoresist.

ITO sputtering conditions: apparatus: an RF magnetron sputtering apparatus, RF power; 40 W, sputtering gas flow rate; Ar=12.0 sccm.

(6) Formation of Contact Hole (FIG. 11)

Subsequently, patterning was conducted by a photolithographic etching method in a similar manner to the patterning of the gate electrode, and the other areas than the portion where a contact hole was to be formed were protected by a photoresist. Thereafter, a hole was formed in the gate insulation film with buffered hydrofluoric acid as an etching liquid to expose the gate electrode, and the photoresist was removed in a similar manner to the pattering of the gate electrode, thereby forming a contact hole.

(7) Formation of Connection Electrode (and Common Wiring Lines and Signal Wiring Lines) (FIGS. 12a and 12b)

Thereafter, a layer of Mo was formed to a thickness of 200 nm by sputtering. The sputtering conditions were the same as those described in the above gate electrode formation step.

Subsequently, patterning was conducted by a photolithographic etching method in a similar manner to the patterning of the gate electrode, thereby forming a connection electrode, common wiring lines and signal wiring lines.

(8) Formation of Insulation Film (FIG. 13)

Thereafter, a layer of photosensitive polyimide was formed to a thickness of 2 μm, and patterning was performed by a photolithographic etching method, thereby forming an insulation film.

The conditions for application and patterning were as follows.

Application: spin coating at 1,000 rpm for 30 sec.

Exposure: 20 sec. (g line of a super high pressure mercury lamp; energy equivalent to 400 mJ/cm²)

Development: developer; NMD-3 (manufactured by TOKTO OHKA KOGYO CO., LTD.), immersed for 1 min. and agitated for 1 min.

Rinse: pure water ultrasonic wave washing for 1 min. (twice) and 5 min. (once), and N₂ blowing

Post-baking: at 120° C. for 1 hour

A TFT substrate for an organic EL display device was prepared by the above-described steps.

(9) Preparation of Organic EL Element (FIG. 14)

On a TFT substrate that has been subjected to an oxygen plasma treatment, a hole injection layer, a hole transport layer, a luminescent layer, a hole blocking layer, an electron transport layer and an electron injection layer were sequentially formed, and a cathode was formed by patterning with a shadow mask. Each layer was formed by a resistance heat vacuum deposition method.

The conditions for the oxygen plasma treatment and the configuration of each layer are as follows.

Oxygen plasma treatment: O₂ flow rate; 10 sccm, RF power: 200 W, treatment time; 1 min.

Hole injection layer: 4,4′,4″-tris(2-naphthyl phenylamino)triphenylamine (referred to as “2-TNATA”); 140 nm in thickness

Hole transport layer: N-N′-dinaphthyl-N,N′-diphenyl-[1,1′-biphenyl]-4,4′-diamine (referred to as “α-NPD”); 10 nm in thickness.

Luminescent layer: a layer containing 4,4′-di-(N-carbazole)-biphenyl (referred to as “CBP”), and fac-tris(2-phenylpyridinate-N,C2′)iridium (III) (referred to as “Ir(ppy)₃”) in an amount of 5% by mass relative to CBP; 20 nm in thickness.

Hole blocking layer: bis-(2-methyl-8-quinonylphenolate) aluminium (referred to as “BAlq”); 10 nm in thickness.

Electron transport layer: tris(8-hydroxyquinoninate)aluminium (referred to as “Alq3”); 20 nm in thickness.

Electron injection layer: LiF; 1 nm in thickness.

Cathode: Al; 200 nm in thickness.

(10) Sealing Step

On the TFT substrate having the organic EL element thereon, a layer of SiNₓ was formed to a thickness of 2 μm as a sealing layer by a plasma CVD (PECVD) method. Further, a protective film (a PEN film having a SiON layer deposited thereon to a thickness of 50 nm) was adhered to the sealing layer with a thermosetting epoxy resin adhesive (at 90° C. for 3 hours).

### 2. Performance of Organic EL Display Device

The organic EL display device 1 prepared by the above-described process emitted green light at a luminance of 600 cd/m² which was twice as high as that of conventional devices, under the conditions of applied voltages of 20 V to common wires; 18 V to signal wires, and 10 V to scanning wires.

Further, there was no short circuit between the cathode and the anode (pixel electrode) of the organic EL element, and an excellent green color was displayed.

### Example 2

An organic EL display device as shown in FIG. 2 was prepared. In this configuration, the pixel electrode portion does not have a gate insulation film.

1. Preparation of Organic EL Display Device

An organic EL display device 2 was prepared in a similar manner to Example 1 except that the formation of a gate insulation film and the formation of a contact hole in Example 1 were changed as follows.

(1) Formation of Gate Insulation Film

A layer of SiNₓ having a thickness of 400 nm was formed as the gate insulation film, in place of the gate insulation film of SiO₂ in Example.

Sputtering was conducted under the conditions of an RF power of 400 W and a sputtering gas flow rate of Ar=12.0 sccm, using Si₃N₄ as a target material, by an RF magnetron sputtering apparatus.

(2) Formation of Contact Hole

In the forming step of the contact hole in Example 1, the patterning by the photolithographic etching was changed such that the gate insulation film at the pixel electrode portion was also removed together with the film at the contact hole portion by etching.

### 2. Performance of Organic EL Display Device

The result of the evaluation conducted in a similar manner to Example 1 showed that the organic EL display device 2 of the present invention had such an advantage that the light emitted from the luminescent layer was extracted from the substrate 11 at a high luminance without being absorbed by the gate insulation film, since the organic EL display device 2 does not have the gate insulation film at the pixel electrode portion.

### Example 3

### 1. Preparation of Organic EL Display Device

An organic EL display device 3 of the invention was prepared in a similar manner to Example 1 except that the formation processes of the source and drain electrodes, pixel electrode, contact hole and connection electrode (and signal wire and common wire), after formation of the active and resistive layers, were changed as follows.

(1) Formation of Contact Hole

A contact hole was prepared by patterning by a photolithographic etching method in a similar manner to the formation of the contact hole in Example 1.

(2) Formation of Source Electrode, Drain Electrode, Pixel Electrode and Connection Electrode (Common Wire and Signal Wire)

The source electrode, drain electrode, pixel electrode, connection electrode, common wire and signal wire were prepared by using the same material in the same step, in a similar manner to the formation processes of the source and drain electrodes and pixel electrode in Example 1. The patterning was conducted by a photolithographic etching method in a similar manner to Example 1.

Accordingly, in Example 3, the production process can be simplified, and the source electrode, drain electrode, pixel electrode, connection electrode, signal wire and common wire can be deposited stably and uniformly in a single step, and no further steps for forming electrical contacts among these wirings are required, so that the possibility of occurrence of failures such as breaking of wires due to contact defects can be eliminated, thereby improving reliability and durability.

Performance of Organic EL Display Device

The result of the evaluation conducted in a similar manner to that in Example 1 showed that the organic EL display device 3 emitted light at the same level of luminance as the light obtained in Example 1.

### Example 4

### 1. Preparation of Organic EL Display Device

An organic EL display device 4 employing a top gate type TFT shown in FIG. 4 as a drive TFT was prepared

(1) Formation of Substrate Insulation Film

A substrate insulation film was prepared by depositing SiON by sputtering on a PEN film to a thickness of 50 nm.

The sputtering was conducted under the conditions of an RF power of 400 W and a sputtering gas flow rate of Ar/O₂=12.0/3.0 sccm, using Si₃N₄ as a target material, by an RF magnetron sputtering apparatus.

(2) Formation of Source and Drain Electrodes and Pixel Electrode

After washing the above substrate, a layer of ITO was formed to a thickness of 40 nm by sputtering. Subsequently, patterning was conducted by a photolithographic etching method similarly to the patterning of the above gate electrode, thereby forming source and drain electrodes and a pixel electrode.

The ITO sputtering was conducted under the conditions of an RF power of 40 W and a sputtering gas flow rate of A=12.0 sccm, by an RF magnetron sputtering apparatus.

The patterning process by a photolithographic etching method was similar to the patterning process for the gate electrode in Example 1, except that oxalic acid was used as an etching liquid.

(3) Formation of Common and Signal Wires

A layer of Mo was formed to a thickness of 200 nm by sputtering.

The Mo sputtering was performed under the same conditions as the sputtering conditions in the above gate electrode formation step.

Subsequently, patterning was conducted by a photolithographic etching method in a similar manner to the pattering of the gate electrode in Example 1, thereby forming common and signal wires.

(4) Formation of Resistive and Active Layers

A low electroconductive IGZO film (resistive layer) having a thickness of 40 nm and a high electroconductive IGZO film (active layer) having a thickness of 10 nm were sequentially layered by sputtering, and patterning was conducted by a photoresist method to form a resistive layer and an active layer.

The sputtering conditions of the low electroconductive IGZO film and the high electroconductive IGZO film were as follows.

Low electroconductive IGZO film: apparatus; an RF magnetron sputtering apparatus, RF power; 200 W, sputtering gas flow rate; Ar/O₂=12.0/1.6 sccm, target; a polycrystalline sintered body having a composition of InGaZnO₄.

High electroconductive IGZO film: apparatus; an RF magnetron sputtering apparatus, RF power; 200 W, sputtering gas flow rate; Ar/O₂=12.0/0.6 sccm, target; a polycrystalline sintered body having a composition of InGaZnO₄.

The patterning process by a photolithographic etching method was similar to the patterning process for the gate electrode in Example 1, except that hydrochloric acid was used as an etching liquid.

(5) Formation of Gate Insulation Film

A layer of SiO₂ was formed to a thickness of 200 nm by sputtering to form a gate insulation film.

The sputtering was conducted under the conditions of an RF power of 400 W and a sputtering gas flow rate of Ar/O₂=12.0/2.0 sccm, by an RF magnetron sputtering apparatus.

(6) Formation of Contact Hole and Pixel Area

After protecting the other portion than the contact hole portion and pixel area with a photoresist by patterning according to a photolithographic etching method, a hole was formed in the gate insulation film with buffered hydrofluoric acid as an etching liquid to expose the gate electrode and the pixel area. The photoresist was then stripped off in a similar manner to, the pattering of the gate electrode, thereby forming the contact hole and pixel area.

(7) Formation of Gate Electrode and Connection Electrode (and Scanning Wires)

Mo was deposited to a thickness of 100 nm by sputtering. Next, a photoresist was applied and a photomask was superposed thereon, and the photoresist was exposed via the photomask. The unexposed portions of the photoresist were cured by heating. The uncured portions were removed with an alkali developer. Thereafter, an electrode etching liquid was applied to dissolve and remove the portions corresponding to the electrodes which had not been covered with the cured photoresist. Lastly, the photoresist was stripped off to finish the patterning step. The patterned gate electrodes (and scanning wires) were thus formed.

The patterning step by a photolithographic etching method was similar to the patterning step of the gate electrode in Example 1.

(8) Formation of Insulation Film

A photosensitive polyimide was applied to a thickness of 2 μm, and patterning was performed by a photolithographic etching method to form an insulation film.

The conditions for application and patterning were as follows. Application: spin coating at 1,000 rpm for 30 sec.

Exposure: 20 sec. (g line of a super high pressure mercury lamp; energy equivalent to 400 mJ/cm²)

Development: developer; NMD-3 (manufactured by TOKTO OHKA KOGYO CO., LTD.), immersed for 1 min. and agitated for 1 min.

Rinse: pure water ultrasonic wave washing for 1 min. (twice) and 5 min. (once), and N₂ blowing

Post baking: at 120° C. for 1 hour.

In accordance with the above steps, a TFT substrate for an organic EL display device was prepared.

(9) Preparation of Organic EL Element

A hole injection layer, a hole transport layer, a luminescent layer, a hole blocking layer, an electron transport layer and an electron injection layer were sequentially formed onto the TFT substrate prepared as above, in a similar manner to the preparation of the organic EL display device in Example 1, and a cathode was formed by patterning with a shadow mask, and sealed in a similar manner to Example 1.

### 2. Performance of Organic EL Display Device

The organic EL display device 4 prepared by the above-described process emitted green light at a luminance of 620 cd/m² which was twice as high as that of conventional devices, under the conditions of applied voltages of 20 V to common wires; 18 V to signal wires, and 10 V to scanning wires.

Further, there was no short circuit between the cathode and the anode (pixel electrode) of the organic EL element, and an excellent green color was displayed.

### Example 5

### 1. Preparation of Organic EL Display Device 5

The TFT prepared in Example 1 was subjected to an oxygen plasma treatment under the conditions of O₂ flow rate; 10 sccm, RF power; 200 W, and treatment time; 1 min.

After the above oxygen plasma treatment, the TFT substrate was provided with the following hole injection layer, hole transport layer, luminescent layer, hole blocking layer, electron transport layer and electron injection layer in this order, and a cathode was formed by patterning with a shadow mask. Each layer was formed by a resistance heat vacuum deposition method.

Hole injection layer: 2-TNATA and 2,3,5,6-tetrafluoro-7,7,8,8-tetracyanoquinodimethane (referred to as “F4-TCNQ”) in an amount of 1% by mass with respect to 2-TNATA; 160 nm in thickness.

Hole transport layer: α-NPD; 10 nm in thickness

Luminescent layer: N,N′-dicarbazolyl-3,5-benzene (referred to as “mCP”) and a platinum complex Pt-1 in an amount of 13% by mass with respect to mCP; 60 nm in thickness.

Hole blocking layer: BAlq; 40 nm in thickness.

Electron transport layer: Alq3; 10 nm in thickness.

Electron injection layer: LiF; 1 nm in thickness.

Cathode (upper electrode): Al; 200 nm in thickness.

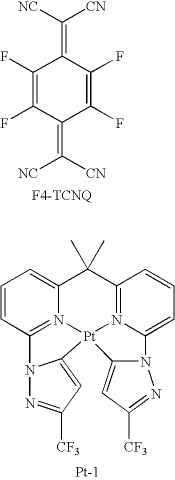

### 2. Performance of Organic EL Display Device

The organic EL display device 5 prepared by the above-described process emitted blue light at a luminance of 340 cd/m² which was twice as high as that of conventional devices, under the conditions of applied voltages of 20 V to common wires; 18 V to signal wires, and 10 V to scanning wires.

Further, there was no short circuit between the cathode and the anode (pixel electrode) of the organic EL element, and an excellent blue color was displayed.

As mentioned above, according to the invention, by employing a TFT including an amorphous oxide semiconductor having a high field effect mobility and a high on/off ratio as a drive TFT, an organic EL display device having a high luminance, high efficiency and high reliability can be provided. In particular, an organic EL display device having a high luminance, high efficiency and high reliability that can be formed on a flexible resin substrate can be provided.

1. An organic electroluminescent display device comprising:
an organic electroluminescent element comprising an organic layer comprising a luminescent layer disposed between a pixel electrode and an upper electrode; and
a drive TFT that supplies an electric current to the organic electroluminescent element, wherein:
the drive TFT comprises a substrate, a gate electrode, a gate insulation film, an active layer, a source electrode and a drain electrode, and wherein:
a resistive layer is provided between the active layer and at least one of the source electrode and the drain electrode.

2. The organic electroluminescent display device according to claim 1, wherein the electroconductivity of the resistive layer is smaller than the electroconductivity of the active layer.

3. The organic electroluminescent display device according to claim 1, wherein the active layer is in contact with the gate insulation film and the resistive layer is in contact with the at least one of the source electrode and the drain electrode.

4. The organic electroluminescent display device according to claim 1, wherein the thickness of the resistive layer is greater than the thickness of the active layer.

5. The organic electroluminescent display device according to claim 1, wherein the electroconductivity between the resistive layer and the active layer changes continuously.

6. The organic electroluminescent display device according to claim 1, wherein the active layer and the resistive layer contain an oxide semiconductor.

7. The organic electroluminescent display device according to claim 6, wherein the oxide semiconductor is an amorphous oxide semiconductor.

8. The organic electroluminescent display device according to claim 6, wherein the oxygen concentration of the active layer is lower than the oxygen concentration of the resistive layer.

9. The organic electroluminescent display device according to claim 6, wherein the oxide semiconductor contains at least one selected from the group consisting of In, Ga and Zn, and a composite oxide thereof.

10. The organic electroluminescent display device according to claim 9, wherein the oxide semiconductor contains In and Zn, and wherein the composition ratio of Zn and In (expressed by Zn/In) of the resistive layer is higher than the composition ratio of Zn/In of the active layer.

11. The organic electroluminescent display device according to claim 1, wherein the electroconductivity of the active layer is 10⁻⁴ Scm⁻¹ or more and less than 10² Scm⁻¹.

12. The organic electroluminescent display device according to claim 1, wherein the ratio of the electroconductivity of the active layer to the electroconductivity of the resistive layer (electroconductivity of the active layer/electroconductivity of the resistive layer) is from 10² to 10⁸.

13. The organic electroluminescent display device according to claim 1, wherein the substrate is a flexible resin substrate.

14. The organic electroluminescent display device according to claim 1, wherein at least one of the source electrode and the drain electrode of the drive TFT, and the pixel electrode of the organic electroluminescent element, are made of the same material and are formed in the same process.

15. The organic electroluminescent display device according to claim 14, wherein the at least one of the source electrode and the drain electrode of the drive TFT is made of indium tin oxide or indium zinc oxide.

16. The organic electroluminescent display device according to claim 14, wherein an insulation film is formed on the periphery of the pixel electrode of the organic electroluminescent element.
